(19) United States
(12) Patent Application Publication
(10) Pub. No.: US 2021/0335766 A1
(43) Pub. Date: Oct. 28, 2021

(54) DISPLAY DEVICE AND METHOD OF MANUFACTURING THE SAME

(71) Applicant: Seoul National University R&DB Foundation, Seoul (KR)

(72) Inventors: Euijoon YOON, Seoul (KR); Jehong OH, Seoul (KR); Seungmin LEE, Seoul (KR); Jongmyeong KIM, Uiwang-si (KR); Jungel RYU, Seoul (KR)

(21) Appl. No.: 17/238,184

(22) Filed: Apr. 22, 2021

(30) Foreign Application Priority Data
Apr. 23, 2020 (KR) 10-2020-0049144
Feb. 22, 2021 (KR) 10-2021-0023127

(51) Int. Cl. H01L 25/16; H01L 33/40; H01L 21/68

(52) U.S. Cl. CPC H01L 25/167; H01L 33/20; H01L 21/68; H01L 33/40

(57) ABSTRACT

Disclosed are a display device and a method of manufacturing the same. The display device includes a plurality of pixels on a base layer and a plurality of light emitting devices provided on a first pixel, which is one of the pixels. The light emitting devices include at least one active light emitting device and at least one dummy light emitting device. Each of the active and dummy light emitting devices includes a first surface and a second surface, which are opposite to each other, and a metal oxide pattern on the second surface. The first surface of the active light emitting device faces the base layer, and the second surface of the dummy light emitting device faces the base layer.

### CROSS-REFERENCE TO RELATED APPLICATIONS

This U.S. non-provisional patent application claims priority under 35 U.S.C. §119 to Korean Patent Application Nos. 10-2020-0049144 and 10-2021-0023127, filed on Apr. 23, 2020 and Feb. 22, 2021, respectively, in the Korean Intellectual Property Office, the entire contents of which are hereby incorporated by reference.

### BACKGROUND

The present disclosure relates to a display device with improved light-emitting efficiency and improved production efficiency and a method of manufacturing the same.

A display device includes a light emitting device. The light emitting device is electrically connected to an electrode and emits light in response to a voltage applied to the electrode. The light emitting device may be directly formed on the electrode. Alternatively, the light emitting device may be formed and then may be placed on the electrode.

The light emitting device may be a light-emitting diode (LED). The LED is a semiconductor device converting an energy, which is generated from recombination of holes and electrons when forward voltage is applied to a pn junction diode, to light energy. The LED may be classified into an inorganic LED or an organic LED. The LED may be used not only in small-sized electronic products such as cellphones, but also in large-sized electronic products such as television sets.

### SUMMARY

An embodiment of the inventive concept provides a display device with improved light-emitting efficiency.

An embodiment of the inventive concept provides a method of manufacturing a display device process-effectively and cost-effectively.

According to an embodiment of the inventive concept, a display device may include a plurality of pixels on a base layer and a plurality of light emitting devices provided on a first pixel, which is one of the pixels. The light emitting devices may include at least one active light emitting device and at least one dummy light emitting device. Each of the active and dummy light emitting devices may include a first surface and a second surface, which are opposite to each other, and a metal oxide pattern on the second surface. The first surface of the active light emitting device may face the base layer, and the second surface of the dummy light emitting device may face the base layer.

According to an embodiment of the inventive concept, a method of manufacturing a display device may include forming a first electrode and a partition wall structure, which exposes the first electrode, on a base layer, supplying micro-LED flakes on the base layer, performing a thermal treatment process to adhere an active light emitting device, which is one of the supplied micro-LED flakes, to the first electrode, and retrieving the remaining ones of the micro-LED flakes, except the active light emitting device adhered to the first electrode.

### BRIEF DESCRIPTION OF THE DRAWINGS

FIG. 1 is a block diagram illustrating a display device according to an embodiment of the inventive concept.

FIG. 2 is an equivalent circuit diagram illustrating a pixel according to an embodiment of the inventive concept.

FIG. 3 is a plan view illustrating a display panel of a display device according to an embodiment of the inventive concept.

FIG. 4A is a sectional view taken along a line A-A′ of FIG. 3.

FIG. 4B is a sectional view taken along a line B-B′ of FIG. 3.

FIG. 5A is a perspective view illustrating a light emitting device of FIG. 3.

FIG. 5B is a perspective view illustrating an inverted structure of the light emitting device of FIG. 5A.

FIG. 6 is a plan view illustrating a display panel of a display device according to an embodiment of the inventive concept.

FIG. 7 is a sectional view taken along a line A-A′ of FIG. 6.

FIG. 8 is an enlarged plan view of a first pixel of FIG. 6.

FIGS. 9, 11, and 13 are plan views illustrating a method of manufacturing a display panel of a display device according to an embodiment of the inventive concept.

FIGS. 10, 12, and 14 are sectional views taken along lines A-A′ of FIGS. 9, 11, and 13, respectively.

FIG. 15 is a schematic diagram illustrating an apparatus for placing light emitting devices according to an embodiment of the inventive concept.

FIGS. 16, 21, and 23 are plan views illustrating a method of manufacturing a display panel of a display device, according to an embodiment of the inventive concept.

FIGS. 17, 22, and 24 are sectional views taken along lines A-A′ of FIGS. 16, 21, and 23, respectively.

FIGS. 18A and 18B are conceptual diagrams illustrating a method of retrieving micro-LED flakes, according to an embodiment of the inventive concept.

FIGS. 19A and 19B are conceptual diagrams illustrating a method of retrieving micro-LED flakes, according to another embodiment of the inventive concept.

FIGS. 20A and 20B are conceptual diagrams illustrating a method of retrieving micro-LED flakes, according to other embodiment of the inventive concept.

FIG. 25 is a plan view illustrating a display panel of a display device according to an embodiment of the inventive concept.

### DETAILED DESCRIPTION

In order to sufficiently understand the configuration and effect of the inventive concept, some embodiments of the inventive concept will be described with reference to the accompanying drawings. It should be noted, however, that the inventive concept are not limited to the following exemplary embodiments, and may be implemented in various forms. Rather, the exemplary embodiments are provided only to disclose the inventive concept and let those skilled in the art fully know the scope of the inventive concept.

In this description, it will be understood that, when an element is referred to as being on another element, the element can be directly on the other element or intervening elements may be present therebetween. In the drawings, thicknesses of some components are exaggerated for effectively explaining the technical contents. Like reference numerals refer to like elements throughout the specification.

Some example embodiments detailed in this description will be discussed with reference to sectional and/or plan views as ideal exemplary views of the inventive concept. In the drawings, thicknesses of layers and regions are exaggerated for effectively explaining the technical contents. Accordingly, regions exemplarily illustrated in the drawings have general properties, and shapes of regions exemplarily illustrated in the drawings are used to exemplarily disclose specific shapes but not limited to the scope of the inventive concept. It will be understood that, although the terms “first”, “second”, “third”, etc. may be used herein to describe various elements, these elements should not be limited by these terms. These terms are only used to distinguish one element from another element. The embodiments explained and illustrated herein include complementary embodiments thereof.

The terminology used herein is for the purpose of describing particular embodiments only and is not intended to limit the inventive concept. As used herein, the singular forms are intended to include the plural forms as well. The terms ‘comprises/includes’ and/or ‘comprising/including’ used in the specification do not exclude the presence or addition of one or more other components.

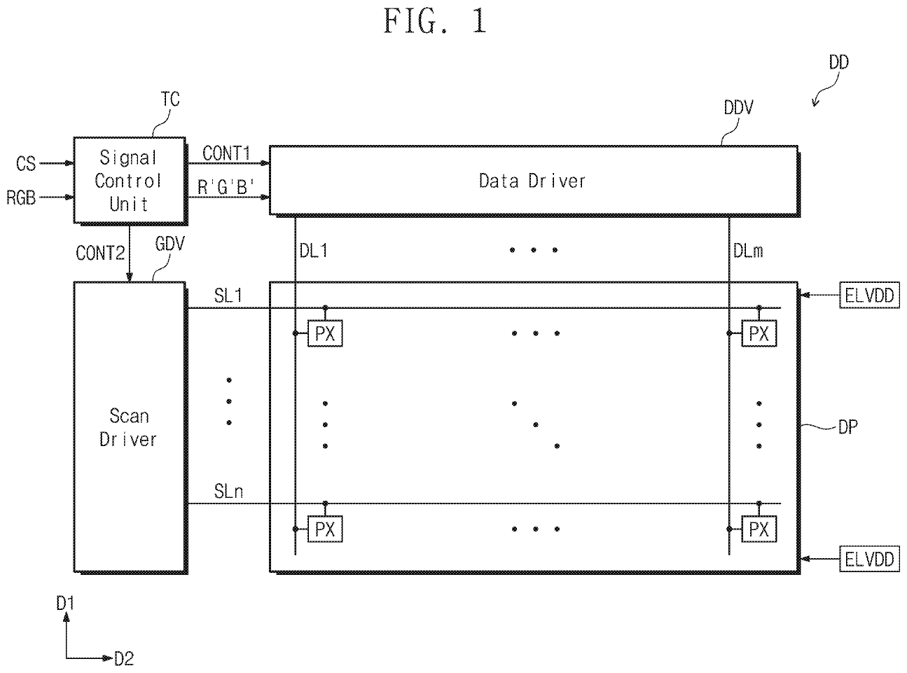

FIG. 1 is a block diagram illustrating a display device according to an embodiment of the inventive concept.

Referring to FIG. 1, a display device DD may include a display panel DP, a signal control unit TC or a timing controller, a data driver DDV, and a scan driver GDV. Each of the signal control unit TC, the data driver DDV, and the scan driver GDV may include a circuit.

The display panel DP may include a light emitting device. For example, the display panel DP may include a micro-LED. The display panel DP may include a plurality of data lines DL1 to DLm, a plurality of scan lines SL1 to SLn, and a plurality of pixels PX.

The data lines DL1 to DLm may be extended in a first direction D1. The data lines DL1 to DLm may be arranged in a second direction D2 crossing the first direction D1. The scan lines SL1 to SLn may be extended in the second direction D2. The scan lines SL1 to SLn may be arranged in the first direction D1.

Each of the pixels PX may include a light emitting device and a pixel circuit electrically connected to the light emitting device. The pixel circuit may include a plurality of transistors. A first power voltage ELVDD and a second power voltage ELVSS may be provided in each of the pixels PX.

The pixels PX may be arranged on a surface of the display panel DP, in a regular manner or with a specific arrangement rule. Each of the pixels PX may be configured to display one of primary colors or one of mixed colors. The primary colors may include red, green, and blue colors. The mixed colors may include yellow, cyan, magenta, and white colors. However, colors, which can be displayed by the pixels PX, are not limited to the above colors.

The signal control unit TC may receive an image data RGB provided from the outside. The signal control unit TC may be configured to convert the image data RGB to image data R′G′B′, which are suitable for operations of the display panel DP, and to output the converted image data R′G′B′ to the data driver DDV.

The signal control unit TC may receive a control signal CS provided from the outside. The control signal CS may include a vertical synchronization signal, a horizontal synchronization signal, a main clock signal, and a data enable signal. The signal control unit TC may provide a first control signal CONT1 to the data driver DDV and may provide a second control signal CONT2 to the scan driver GDV. The first control signal CONT1 may be used to control the data driver DDV, and the second control signal CONT2 may be used to control the scan driver GDV.

The data driver DDV may drive the data lines DL1 to DLm, in response to the first control signal CONT1 provided from the signal control unit TC. The data driver DDV may be provided in the form of a separate integrated circuit, and then it may be electrically connected to a portion of the display panel DP or may be directly mounted on the display panel DP. In an embodiment, the data driver DDV may be provided in the form of a single chip or a plurality of chips.

The scan driver GDV may drive the scan lines SL1 to SLn, in response to the second control signal CONT2 provided from the signal control unit TC. As an example, the scan driver GDV may be integrated on a region of the display panel DP. In this case, the scan driver GDV may include a plurality of thin-film transistors that are formed by the same process as that for a driving circuit of the pixel PX (e.g., by a low temperature polycrystalline silicon (LTPS) process or a low temperature polycrystalline oxide (LTPO) process). Alternatively, the scan driver GDV may be provided in the form of a separate integrated circuit chip and then may be electrically connected to a portion of the display panel DP.

In the case where one of the scan lines SL1 to SLn is applied with a gate-on voltage, switching transistors in a row of pixels connected thereto may be turned on. Here, the data driver DDV may provide data driving signals to the data lines DL1 to DLm. The data driving signals provided to the data lines DL1 to DLm may be applied to corresponding pixels through the turned-on switching transistors. The data driving signals may be analog voltages corresponding to gradation levels of the image data.

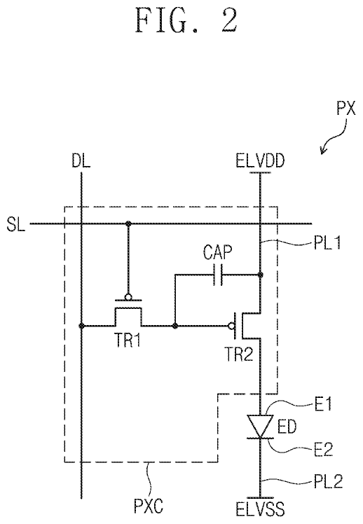

FIG. 2 is an equivalent circuit diagram illustrating a pixel according to an embodiment of the inventive concept.

Referring to FIG. 2, the pixel PX may be connected to a plurality of signal lines. In the present embodiment, the signal lines may include a scan line SL, a data line DL, a first power line PL1, and a second power line PL2.

The pixel PX may include a light emitting device ED and a pixel circuit PXC. The pixel circuit PXC may include a first thin-film transistor TR1, a capacitor CAP, and a second thin-film transistor TR2.

The first thin-film transistor TR1 may be a switching transistor, which is used to control the on/off operation of the pixel PX. The first thin-film transistor TR1 may transmit or block a data signal transmitted through the data line DL, in response to a gate signal transmitted through the scan line GL.

The capacitor CAP may be provided between and connected to the first thin-film transistor TR1 and the first power line PL1. An amount of electric charges stored in the capacitor CAP may vary depending on a difference in voltage between the data signal transmitted from the first thin-film transistor TR1 and the first power voltage ELVDD applied to the first power line PL1.

The second thin-film transistor TR2 may be connected to the first thin-film transistor TR1, the capacitor CAP, and the light emitting device ED. The second thin-film transistor TR2 may control a driving current flowing through the light emitting device ED, based on the amount of charges stored in the capacitor CAP. For example, a turn-on time of the second thin-film transistor TR2 may be determined depending on the amount of charges stored in the capacitor CAP.

The first and second thin-film transistors TR1 and TR2 may be n-type or p-type thin-film transistors. Alternatively, at least one of the first and second thin-film transistors TR1 and TR2 may be an n-type thin-film transistor, and the other may be a p-type thin-film transistor.

The light emitting device ED may be provided between and connected to the second thin-film transistor TR2 and the second power line PL2. The light emitting device ED may emit light, when there is a difference in voltage between a signal transmitted through the second thin-film transistor TR2 and the second power voltage ELVSS received through the second power line PL2.

The light emitting device ED may be an ultra-small LED device. The ultra-small LED device may be an LED device whose size is in a range from several nano-meters to several hundreds of micro-meters. However, the size of the ultra-small LED device is merely illustrative example, and is not limited to the afore-mentioned size range.

An example, in which just one light emitting device ED is provided between the second thin-film transistor TR2 and the second power line PL2, is illustrated in FIG. 2, but, in an embodiment, a plurality of light emitting devices ED may be provided. The plurality of the light emitting devices ED may be connected in parallel to each other.

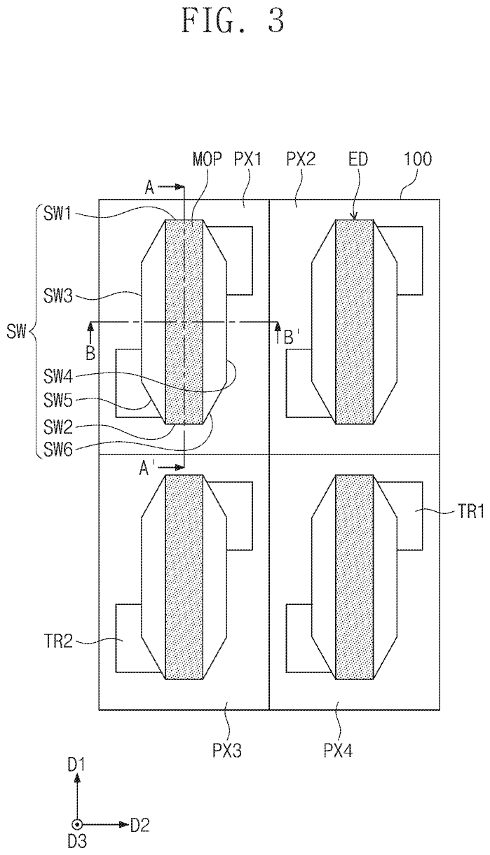

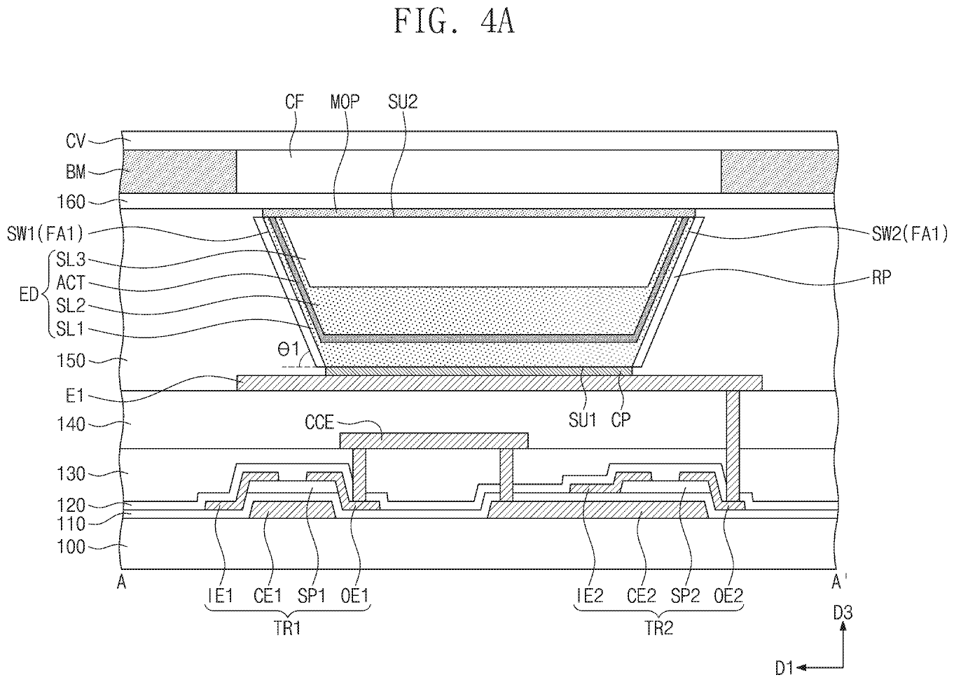

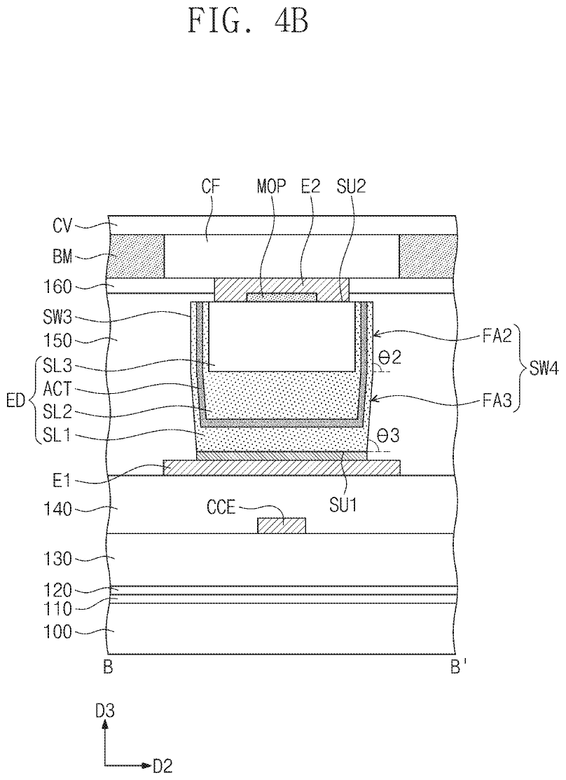

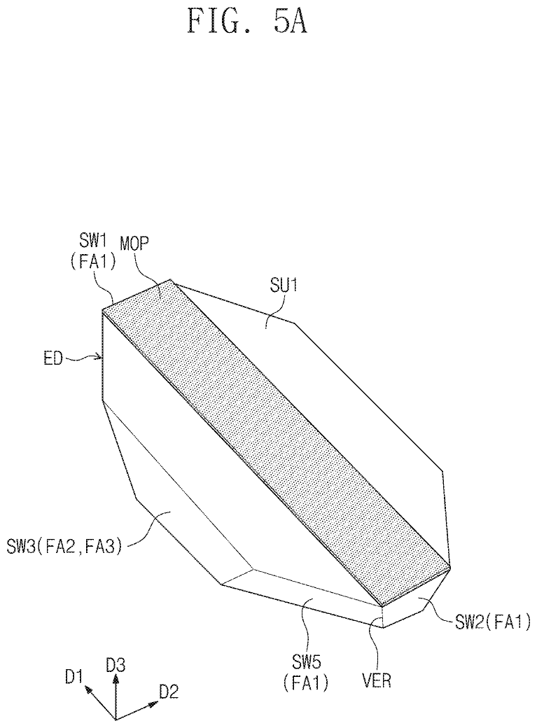

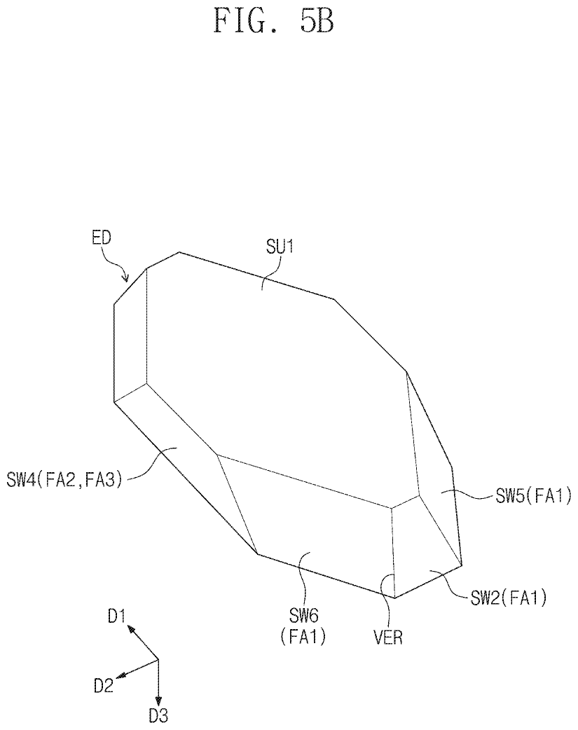

FIG. 3 is a plan view illustrating a display panel of a display device according to an embodiment of the inventive concept. FIG. 4A is a sectional view taken along a line A-A′ of FIG. 3. FIG. 4B is a sectional view taken along a line B-B′ of FIG. 3. FIG. 5A is a perspective view illustrating a light emitting device of FIG. 3. FIG. 5B is a perspective view illustrating an inverted structure of the light emitting device of FIG. 5A.

Referring to FIGS. 3, 4A, 4B, 5A, and 5B, first to fourth pixels PX1 to PX4 may be provided on a base layer 100. The base layer 100 may include a silicon substrate, a plastic substrate, a glass substrate, an insulating film, or a stack including a plurality of insulating layers.

The first to fourth pixels PX1 to PX4 may be two-dimensionally arranged. The first and second pixels PX1 and PX2 may be adjacent to each other in the second direction D2, and the third and fourth pixels PX3 and PX4 may be adjacent to each other in the second direction D2. The first and third pixels PX1 and PX3 may be adjacent to each other in the first direction D1, and the second and fourth pixels PX2 and PX4 may be adjacent to each other in the first direction D1. Each of the first to fourth pixels PX1 to PX4 may include the first thin-film transistor TR1, the second thin-film transistor TR2, and the light emitting device ED. Hereinafter, one (e.g., the first pixel PX1) of the first to fourth pixels PX1 to PX4 will be exemplarily described.

The first and second thin-film transistors TR1 and TR2 may be disposed on the base layer 100. The first thin-film transistor TR1 may include a first control electrode CE1, a first input electrode IE1, a first output electrode OE1, and a first semiconductor pattern SP1. The second thin-film transistor TR2 may include a second control electrode CE2, a second input electrode IE2, a second output electrode OE2, and a second semiconductor pattern SP2.

The first control electrode CE1 and the second control electrode CE2 may be provided on the base layer 100. The first control electrode CE1 and the second control electrode CE2 may be formed of or include a conductive material. A first insulating layer 110 may be provided on the base layer 100 to cover the first control electrode CE1 and the second control electrode CE2. In other words, the first control electrode CE1 and the second control electrode CE2 may be interposed between the first insulating layer 110 and the base layer 100.

The first semiconductor pattern SP1 and the second semiconductor pattern SP2 may be provided on the first insulating layer 110. Each of the first and second semiconductor patterns SP1 and SP2 may be formed of or include a semiconductor material. For example, the semiconductor material may include at least one of amorphous silicon, poly silicon, single-crystalline silicon, oxide semiconductor materials, or compound semiconductor materials. Each of the first and second semiconductor patterns SP1 and SP2 may include a channel region, which is used as a conduction path of electrons or holes, and a first impurity region and a second impurity region, which are spaced apart from each other with the channel region interposed therebetween.

The first input electrode IE1 and the first output electrode OE1 may be provided on the first semiconductor pattern SP1. The first input electrode IE1 and the first output electrode OE1 may be respectively connected to the first and second impurity regions of the first semiconductor pattern SP1. The second input electrode IE2 and the second output electrode OE2 may be provided on the second semiconductor pattern SP2. The second input electrode IE2 and the second output electrode OE2 may be respectively connected to the first and second impurity regions of the second semiconductor pattern SP2.

A second insulating layer 120 may be provided on the first insulating layer 110 to cover the first and second semiconductor patterns SP1 and SP2, the first and second input electrodes IE1 and IE2, and the first and second output electrodes OE1 and OE2. In other words, the first and second semiconductor patterns SP1 and SP2, the first and second input electrodes IE1 and IE2, and the first and second output electrodes OE1 and OE2 may be interposed between the first insulating layer 110 and the second insulating layer 120.

A third insulating layer 130 may be provided on the second insulating layer 120. The third insulating layer 130 may have a substantially flat top surface. A connection electrode CCE may be disposed on the third insulating layer 130 to electrically connect the first output electrode OE1 to the second control electrode CE2. The connection electrode CCE may include a first contact, which is provided to penetrate the second and third insulating layers 120 and 130 and is coupled to the first output electrode OE1. In addition, the connection electrode CCE may include a second contact, which is provided to penetrate the first to third insulating layers 110, 120, and 130 and is coupled to the second control electrode CE2.

A fourth insulating layer 140 may be provided on the third insulating layer 130 to cover the connection electrode CCE. A first electrode E11 may be provided on the fourth insulating layer 140. The first electrode E1 may include a third contact, which is provided to penetrate the second to fourth insulating layers 120, 130, and 140 and is coupled to the second output electrode OE2.

A fifth insulating layer 150 may be provided on the fourth insulating layer 140 to cover the first electrode E1. The light emitting device ED may be provided on the first electrode E1. The light emitting device ED may be provided in the fifth insulating layer 150. The light emitting device ED may have a first surface SU1 and a second surface SU2, which are opposite to each other in a third direction D3. As an example, the first surface SU1 may be a bottom surface of the light emitting device ED, and the second surface SU2 may be a top surface of the light emitting device ED. An area of the first surface SU1 may be smaller than an area of the second surface SU2. In an embodiment, a p-type semiconductor layer of the light emitting device ED may be adjacent to the first surface SU1, and an n-type semiconductor layer of the light emitting device ED may be adjacent to the second surface SU2.

A connection pattern CP may be interposed between the light emitting device ED and the first electrode E1. The connection pattern CP may be provided on the first surface SU1 of the light emitting device ED. The connection pattern CP may be formed of or include at least one of metallic materials (e.g., Ni, Au, alloys of Ni and Au, or a multilayer of Ni/Au layers) having a low melting temperature.

The light emitting device ED and the first electrode E1 may be electrically connected to each other through the connection pattern CP. For example, the light emitting device ED may include a first semiconductor layer SL1, as will be described below, and the first electrode E1 may be connected to the first semiconductor layer SL1 of the light emitting device ED. The first electrode E1 may be a p-type electrode. The first electrode E1 may be electrically connected to the first power line PL1 previously described with reference to FIG. 2. In other words, the first power voltage ELVDD of FIG. 2 may be applied to the first electrode E1.

The light emitting device ED may include a first semiconductor layer SL1, an active layer ACT, a second semiconductor layer SL2, and a third semiconductor layer SL3, which are sequentially stacked. The active layer ACT and the first to third semiconductor layers SL1, SL2, and SL3 may be formed of or include at least one of III-V compound semiconductor materials. The active layer ACT and the first to third semiconductor layers SL1, SL2, and SL3 may be formed of or include at least one of GaN-based semiconductor materials. In an embodiment, the active layer ACT and the first to third semiconductor layers SL1, SL2, and SL3 may be formed of or include at least one of GaN, AlN, AlGaN, InGaN, InN, InAlGaN, AlInN, or combinations thereof.

The first to third semiconductor layers SL1, SL2, and SL3 may be formed of or include the same GaN semiconductor material. As an example, the first to third semiconductor layers SL1, SL2, and SL3 may be formed of or include GaN. The first semiconductor layer SL1 may be a p-type semiconductor layer. The first semiconductor layer SL1 may contain an impurity, such as magnesium (Mg), zinc (Zn), calcium (Ca), strontium (Sr), or barium (Ba). The second semiconductor layer SL2 may be an n-type semiconductor layer. The second semiconductor layer SL2 may contain an impurity, such as silicon (Si), germanium (Ge), tin (Sn), selenium (Se), or tellurium (Te). The third semiconductor layer SL3 may be an undoped semiconductor layer.

The active layer ACT may be interposed between the first semiconductor layer SL1 and the second semiconductor layer SL2. The active layer ACT may be a region, in which holes injected through the first semiconductor layer SL1 are recombined with electrons injected through the second semiconductor layer SL2. As a result of the electron-hole recombination, light may be emitted from the active layer ACT. The active layer ACT may have at least one of a single quantum well structure, a multiple quantum well structure, a quantum wire structure, or a quantum dot structure. As an example, the active layer ACT may have a multiple quantum well structure containing InGaN and GaN.

The first semiconductor layer SL1, the active layer ACT, the second semiconductor layer SL2, and the third semiconductor layer SL3 may be sequentially stacked on the first surface SU1 of the light emitting device ED. Furthermore, the first semiconductor layer SL1, the active layer ACT, the second semiconductor layer SL2, and the third semiconductor layer SL3 may be sequentially stacked on a sidewall SW of the light emitting device ED. In other words, each of the first semiconductor layer SL1, the active layer ACT, and the second semiconductor layer SL2 may have a ‘U’-shaped section. Each of the first semiconductor layer SL1, the active layer ACT, and the second semiconductor layer SL2 may have a shape enclosing bottom and side surfaces of the third semiconductor layer SL3.

The active layer ACT adjacent to the sidewall SW of the light emitting device ED may be interposed between the first semiconductor layer SL1 and the second semiconductor layer SL2. In other words, the active layer ACT adjacent to the sidewall SW of the light emitting device ED may be veiled by the first semiconductor layer SL1 and may not be exposed to the outside. The first semiconductor layer SL1 adjacent to the sidewall SW of the light emitting device ED may passivate the active layer ACT. Since the active layer ACT is protected by the first semiconductor layer SL1, electric characteristics of the active layer ACT may be improved, and thus, light-emitting efficiency of the light emitting device ED may be improved.

A thickness of the first semiconductor layer SL1 in the third direction D3 may be larger than a thickness of the first semiconductor layer SL1 on the sidewall SW of the light emitting device ED. A thickness of the second semiconductor layer SL2 in the third direction D3 may be larger than a thickness of the second semiconductor layer SL2 on the sidewall SW of the light emitting device ED. This is because a GaN growth rate in the third direction D3 is highest in a growth process of the light emitting device ED, which will be described below.

When viewed in a plan view, the light emitting device ED may have an octagonal shape. In an embodiment, although not shown, the light emitting device ED may have one of polygonal shapes (e.g., a hexagonal shape). The light emitting device ED may have a section that is shaped like a truncated inverted pyramid. In other words, the light emitting device ED may be provided to have a shape of a truncated octagonal pillar (e.g., see FIGS. 5A and 5B).

The light emitting device ED may include the sidewall SW, which is slantly extended from the first surface SU1 and the second surface SU2. For example, the sidewall SW may include first to sixth sidewalls SW1 to SW6. The light emitting device ED may further include a vertex VER, which is formed by two of the sidewalls SW meeting each other. For example, the vertex VER may be defined at a point where the second and fifth sidewalls SW2 and SW5 meet. The vertex VER may be extended from the first surface SU1 of the light emitting device ED to the second surface SU2 (e.g., see FIGS. 5A and 5B).

Each of the first surface SU1, the second surface SU2, and the sidewall SW of the light emitting device ED may have a wurtzite crystal structure. Each of the first and second surfaces SU1 and SU2 of the light emitting device ED may be a c-plane that is a polar plane. Each of the first and second surfaces SU1 and SU2 may be a (0001) facet. The polar plane or the c-plane may be a surface that is made up of only one kind of atoms. In an embodiment, the polar plane or the c-plane may be a surface that is made up of only gallium (Ga) atoms or only nitrogen (N) atoms.

The sidewall SW of the light emitting device ED may be inclined at an angle to the first and second surfaces SU1 and SU2. In an embodiment, the first, second, fifth, and sixth sidewalls SW1, SW2, SW5, and SW6 of the light emitting device ED may have the same angle. The third and fourth sidewalls SW3 and SW4 may have the same angle. The first, second, fifth, and sixth sidewalls SW1, SW2, SW5, and SW6 may be inclined at an angle different from the third and fourth sidewalls SW3 and SW4.

Each of the first, second, fifth, and sixth sidewalls SW1, SW2, SW5, and SW6 may include a first facet FA1. The first facet FA1 may be inclined at a first angle θ1 to the first surface SU1. The first angle θ1 may range from 10° to 80°.

The first facet FA1 may be a semi-polar plane. In detail, the first facet FA1 may be a {n −n 0 k} facet. Here, each of indices n and k may be an integer of 1 or greater. As an example, the first facet FA1 may be a {1 −1 0 1} plane.

If the sidewall SW of the light emitting device ED is a surface that is perpendicular to the first surface SU1 (e.g., if the first angle θ1 is about 90°, light generated in the active layer ACT may be leaked through the sidewall SW, and in this case, the light extraction efficiency may be reduced. However, according to an embodiment of the inventive concept, since the light emitting device ED has the sidewall SW that is inclined at an angle, it may be possible to effectively prevent the light from being leaked through the sidewall SW. Accordingly, the light emitting device ED may have high light extraction efficiency.

Each of the third and fourth sidewalls SW3 and SW4 may include a second facet FA2 and a third facet FA3. The second facet FA2 may be positioned on the third facet FA3. The second facet FA2 may be positioned adjacent to the second surface SU2, and the third facet FA3 may be positioned adjacent to the first surface SU1. The second and third facets FA2 and FA3, which are vertically arranged, may connect the first surface SU1 to the second surface SU2 (e.g., see FIG. 4B).

The second facet FA2 may be an a-plane that is a nonpolar plane. The second facet FA2 may be substantially perpendicular to the first surface SU1. The second facet FA2 may be inclined at a second angle θ2 to the first surface SU1. The second angle θ2 may be greater than the first angle θ1. The second angle θ2 may be about 90°. In an embodiment, the second facet FA2 may be a {1 1 −2 0} plane.

The third facet FA3 may be a semi-polar plane. For example, the third facet FA3 may be a {n n −2n k} plane. Here, each of indices n and k may be an integer of 1 or greater. As an example, the third facet FA3 is a {1 1 −2 2} plane. The third facet FA3 may be inclined at a third angle θ3 to the first surface SU1. The third angle θ3 may be greater than the first angle θ1 and may be smaller than the second angle θ2.

Since each of the third and fourth sidewalls SW3 and SW4 further includes not only the second facet FA2 but also the third facet FA3, it may be possible to prevent light, which is generated in the active layer ACT, from being leaked through the sidewall SW and thereby to improve the light extraction efficiency.

According to an embodiment of the inventive concept, due to the inclined shape of the sidewall SW of the light emitting device ED, a width of the light emitting device ED may increase with increasing distance from the base layer 100.

A reflection pattern RP may be interposed between the light emitting device ED and the fifth insulating layer 150. The reflection pattern RP may directly cover the sidewall SW of the light emitting device ED. The reflection pattern RP may prevent the light, which is generated in the active layer ACT, from being leaked through the sidewall SW of the light emitting device ED. In other words, the reflection pattern RP may be configured to reflect the light, which is generated in the active layer ACT, and to guide the light to the second surface SU2 of the light emitting device ED, and thus, the light may be emitted through the second surface SU2 of the light emitting device ED.

A metal oxide pattern MOP may be provided on the second surface SU2 of the light emitting device ED. The metal oxide pattern MOP may directly cover the second surface SU2 of the light emitting device ED. The metal oxide pattern MOP may be provided to cover a portion of the second surface SU2 and to expose the remaining portion. For example, a ratio of an area of the metal oxide pattern MOP to the total area of the second surface SU2 may range from 0.2 to 0.7. The metal oxide pattern MOP may be formed of or include at least one of insulating materials such as metal oxides, and in an embodiment, the metal oxides may include aluminum oxide (i.e., alumina) The metal oxide pattern MOP may be used as a passivation layer covering a portion of the second surface SU2.

The metal oxide pattern MOP may be extended on the second surface SU2 in the first direction D1, which is a direction of a longitudinal axis of the light emitting device ED. For example, the metal oxide pattern MOP may be provided on the second surface SU2 and may be extended from the second sidewall SW2 to first sidewall SW1 (e.g., see FIG. 5A).

As an example, the metal oxide pattern MOP may have a single-crystalline α-phase. As another example, the metal oxide pattern MOP may have a polycrystalline γ-phase. As other example, the metal oxide pattern MOP may have a multi-layered structure, in which single-crystalline α-phase layer and polycrystalline γ-phase layer are stacked.

A second electrode E2 may be provided on the fifth insulating layer 150. The second electrode E2 may be extended in the first direction D1, on the second surface SU2. The second electrode E2 may be connected to a portion of the second surface SU2, which is not veiled by the metal oxide pattern MOP (e.g., see FIG. 4B). The second electrode E2 may be an n-type electrode. The second electrode E2 may be electrically connected to the second power line PL2 previously described with reference to FIG. 2. In other words, the second power voltage ELVSS of FIG. 2 may be applied to the second electrode E2.

Each of the first and second electrodes E1 and E2 may be formed of or include at least one of conductive materials. The conductive materials may include indium zinc oxide (IZO), indium tin oxide (ITO), indium gallium oxide (IGO), indium zinc gallium oxide (IGZO), or combinations thereof. However, the inventive concept is not limited to this example. Alternatively, the conductive materials may include metallic materials including molybdenum, silver, titanium, copper, aluminum, or alloys thereof.

An electrical signal may be applied to the first surface SU1 of the light emitting device ED through the first electrode E1 and the connection pattern CP. The connection pattern CP may be in contact with the first surface SU1 of the light emitting device ED, but not the sidewall SW of the light emitting device ED. Thus, the electrical signal, which is applied to the first electrode E1, may not be supplied to the sidewall SW of the light emitting device ED.

The second electrode E2 may be in contact with only a portion of the second surface SU2, which is not veiled by the metal oxide pattern MOP. Thus, according to an embodiment of the inventive concept, a current between the first and second electrodes E1 and E2 may flow from the first surface SU1 of the light emitting device ED toward the second surface SU2 in a vertical direction (i.e., the third direction D3).

In the light emitting device ED, light may be mainly generated in the c-plane, which is the polar plane. In an embodiment, since the current flows from the first surface SU1 (i.e., the c-plane) toward the second surface SU2 (i.e., the c-plane), the current may be concentrated on the c-planes in the light emitting device ED. Thus, the light-emitting efficiency of the light emitting device ED may be improved.

A light-blocking pattern BM and a color filter CF may be provided on the second electrode E2. The light-blocking pattern BM may have an opening, which is vertically overlapped with the light emitting device ED, and the color filter CF may be provided in the opening. The light-blocking pattern BM may be a black matrix.

The color filter CF may include at least one of a red color filter, a green color filter, or a blue color filter. The color filter CF may be configured to transmit only light of a specific wavelength, among the light emitted from the light emitting device ED. As an example, the color filter CF may include quantum dots. That is, the color filter CF may be a quantum dot color filter.

As an example, the color filter CF may include a transparent material. If the light emitted from the light emitting device ED is a blue light, the color filter CF of a blue pixel may include only a transparent material, without a quantum dot.

A cover layer CV may be provided on the light-blocking pattern BM and the color filter CF. The cover layer CV may be formed of or include transparent glass or transparent plastic. The cover layer CV may protect the color filter CF and the light emitting device ED.

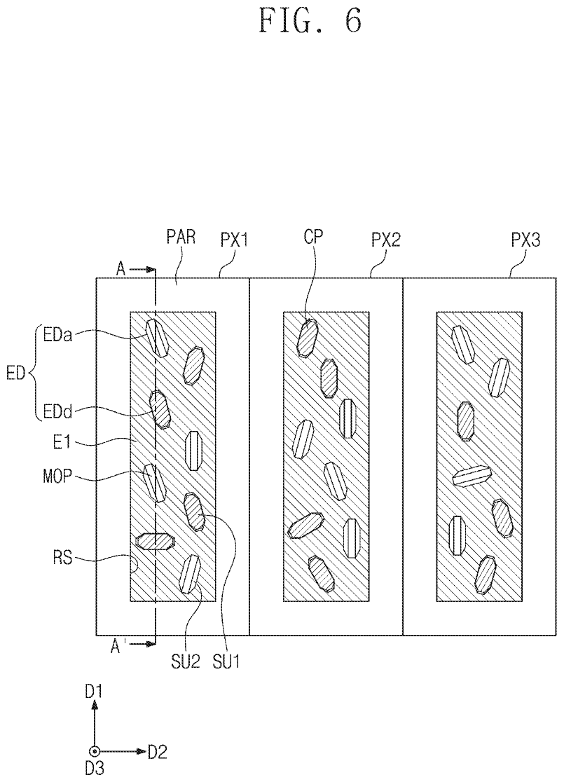

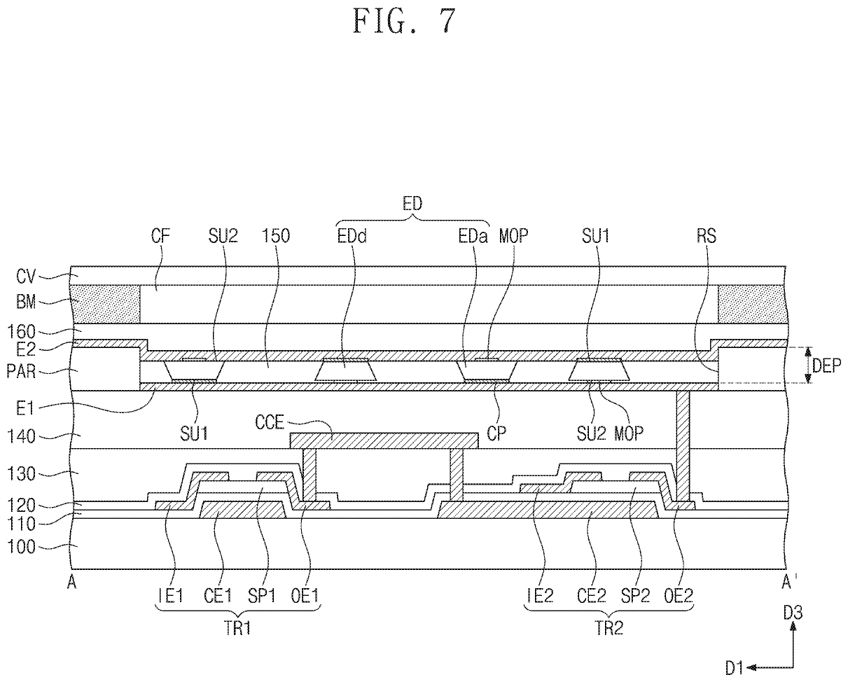

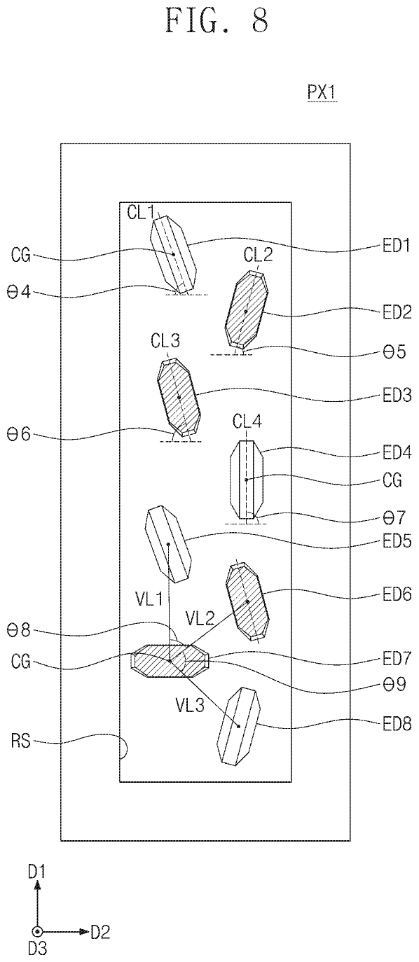

FIG. 6 is a plan view illustrating a display panel of a display device according to an embodiment of the inventive concept. FIG. 7 is a sectional view taken along a line A-A′ of FIG. 6. FIG. 8 is an enlarged plan view of a first pixel of FIG. 6. In the following description of the display device according to the present embodiment, an element previously described with reference to FIGS. 3, 4A, 4B, 5A, and 5B may be identified by the same reference number without repeating an overlapping description thereof.

The display panel of the display device according to the present embodiment may be a large-area display panel. Referring to FIGS. 6 and 7, first to third pixels PX1 to PX3 may be provided on the base layer 100. The large-area display panel according to the present embodiment may include a plurality of pixels, and among such pixels, the first to third pixels PX1 to PX3 are illustrate in FIG. 6 by way of example and without any limitation. The base layer 100 may include a silicon substrate, a plastic substrate, a glass substrate, an insulating film, or a stack including a plurality of insulating layers.

The first to third pixels PX1 to PX3 may be two-dimensionally arranged. As an example, the first to third pixels PX1 to PX3 may be arranged in the second direction D2. Although not shown, additional pixels, along with the first to third pixels PX1 to PX3, may be two-dimensionally arranged on the base layer 100.

Each of the first to third pixels PX1 to PX3 may include a first thin-film transistor TR1, a second thin-film transistor TR2, and a plurality of light emitting devices ED. Hereinafter, one (e.g., the first pixel PX1) of the first to third pixels PX1 to PX3 will be exemplarily described.

The first and second thin-film transistors TR1 and TR2 may be disposed on the base layer 100. The first and second thin-film transistors TR1 and TR2 may be configured to have substantially the same features as those described with reference to FIGS. 3 and 4A.

A partition wall structure PAR may be provided on a fourth insulating layer 140. The partition wall structure PAR may have a bottom surface that is coplanar with a bottom surface of a first electrode E1. The partition wall structure PAR may define a recess region RS exposing the top surface of the first electrode E1. For example, the recess region RS may be defined by an inner sidewall of the partition wall structure PAR and the top surface of the first electrode E1. The recess region RS may be provided to have a specific depth DEP, when measured from a top surface of the partition wall structure PAR.

The plurality of light emitting devices ED may be provided on the first electrode E1 in the recess region RS. Each of the light emitting devices ED may be configured to have substantially the same features as that described with reference to FIGS. 3, 4A, 4B, 5A, and 5B.

The light emitting devices ED may include active light emitting devices EDa and dummy light emitting devices EDd. Each of the active light emitting devices EDa may be disposed in such a way that a first surface SU1 thereof faces the first electrode E1 or the base layer 100. A connection pattern CP may be interposed between the active light emitting device EDa and the first electrode E1. The first surface SU1 of the active light emitting device EDa may be electrically connected to the first electrode E1 through the connection pattern CP. Each of the dummy light emitting devices EDd may be disposed in such a way that a second surface SU2 thereof faces the first electrode E1 or the base layer 100. The second surface SU2 of the dummy light emitting device EDd may be spaced apart from the first electrode E1 by the metal oxide pattern MOP.

A ratio of the number of the active light emitting devices EDa to the total number of the light emitting devices ED may range from about 40% to about 60%. A ratio of the number of the dummy light emitting devices EDd to the total number of the light emitting devices ED may range from about 60% to about 40%. The number of the active light emitting devices EDa may be substantially equal to the number of the dummy light emitting devices EDd, but in an embodiment, they may be different from each other.

In an embodiment, a ratio of the number of the active light emitting devices EDa to the total number of the light emitting devices ED may range from about 60% to about 100%. In other words, the number of the active light emitting devices EDa may be greater than the number of the dummy light emitting devices EDd.

A fifth insulating layer 150 may be provided on the fourth insulating layer 140 to fill a region between the light emitting devices ED. A second electrode E2 may be provided on the fifth insulating layer 150 and the light emitting devices ED. The metal oxide pattern MOP covering the second surface SU2 of the active light emitting device EDa may have a contact hole CTH exposing a center region of the second surface SU2. The second electrode E2 may be in contact with the second surface SU2 of the active light emitting device EDa.

According to an embodiment of the inventive concept, the first electrode E1 may be a p-type electrode, and the second electrode E2 may be an n-type electrode. In the active light emitting device EDa, the p-type or first electrode E1 may be electrically connected to a p-type semiconductor layer adjacent to the first surface SU1 through the connection pattern CP, and the n-type or second electrode E2 may be electrically connected to an n-type semiconductor layer adjacent to the second surface SU2. Thus, the active light emitting device EDa may be used to emit light during an operation of the display device.

By contrast, for the dummy light emitting device EDd, the metal oxide pattern MOP may prevent the first electrode E1 from being in contact with the second surface SU2, while the n-type or second electrode E2 is connected to a p-type semiconductor layer adjacent to the first surface SU1. Thus, the dummy light emitting device EDd may not emit any light, during the operation of the display device. Since the active light emitting devices EDa accounts for about 40% to 60% of the light emitting devices ED, each of the pixels PX1 to PX3 may be used as a normal pixel.

In an embodiment, in the first pixel PX1, a ratio of a total area of the light emitting devices ED to a total area of the first electrode E1 may range from 0.5 to 0.9, when viewed in a plan view. That is, in the first pixel PX1, the total area of the light emitting devices ED may be larger than an area of a region of the first electrode E1, in which the light emitting devices ED are not disposed. Here, the light emitting devices ED may include all of the active and dummy light emitting devices EDa and EDd, as described above.

A sixth insulating layer 160 may be provided on the second electrode E2. The sixth insulating layer 160 may have a flat top surface. A light-blocking pattern BM and a color filter CF may be provided on the sixth insulating layer 160. The light-blocking pattern BM may have an opening, which is vertically overlapped with the recess region RS, and the color filter CF may be provided in the opening. A cover layer CV may be provided on the light-blocking pattern BM and the color filter CF.

The light emitting devices ED, which are randomly arranged in the recess region RS of the first pixel PX1, will be described in more detail with reference to FIG. 8. The light emitting devices ED of the first pixel PX1 may include first to eighth light emitting devices ED1 to ED8. Each of the first to eighth light emitting devices ED1 to ED8 may have a center CG. As an example, the center CG of the light emitting device ED may be a center of gravity of the light emitting device ED.

A first center line CL1 may be defined to pass through the center CG of the first light emitting device ED1. When viewed in a plan view, the first center line CL1 may be parallel to a longitudinal axis of the first light emitting device ED1. Second to fourth center lines CL2 to CL4 of the second to fourth light emitting devices ED2 to ED4 may be defined in the same manner as the first center line CL1 of the first light emitting device EDE

The first to fourth center lines CL1 to CL4 may not be parallel to each other. In other words, since the light emitting devices ED are randomly arranged, the first to fourth center lines CL1 to CL4 may not be parallel to each other. The first to fourth center lines CL1 to CL4 may cross each other. As an example, the first center line CL1 may be inclined at a fourth angle θ4 to the second direction D2, the second center line CL2 may be inclined at a fifth angle θ5 to the second direction D2, the third center line CL3 may be inclined at a sixth angle θ6 to the second direction D2, and the fourth center line CL4 may be inclined at a seventh angle θ7 to the second direction D2. The fourth to seventh angles θ4 to θ7 may be different from each other.

The fifth light emitting device EDS, the sixth light emitting device ED6, and the eighth light emitting device ED8 may be provided adjacent to the seventh light emitting device ED7. A first virtual line VL1 may be defined as a line connecting the center CG of the seventh light emitting device ED7 to the center CG of the fifth light emitting device EDS, a second virtual line VL2 may be defined as a line connecting the center CG of the seventh light emitting device ED7 to the center CG of the sixth light emitting device ED6, and a third virtual line VL3 may be defined as a line connecting the center CG of the seventh light emitting device ED7 to the center CG of the eighth light emitting device ED8.

The first virtual line VL1, the second virtual line VL2, and the third virtual line VL3 may have different lengths from each other. In other words, distances from the fifth light emitting device EDS, the sixth light emitting device ED6, and the eighth light emitting device ED8 to the seventh light emitting device ED7 may be different from each other.

An angle between the first virtual line VL1 and the second virtual line VL2 may be an eighth angle θ8, and an angle between the second virtual line VL2 and the third virtual line VL3 may be a ninth angle θ9. The eighth angle θ8 and the ninth angle θ9 may be different from each other.

The method of manufacturing a display device according to the present embodiment may include randomly scattering micro-LED flakes on the pixels of the display device, and this will be described in more detail below.

Since the micro-LED flakes are randomly scattered on the pixel, the light emitting devices ED on the first electrode E1 may be two-dimensionally and randomly arranged. For example, according to the present embodiment, each of the light emitting devices ED on the first electrode E1 may be the active light emitting device EDa at a probability of 50% or may be the dummy light emitting device EDd at a probability of 50%.

According to the present embodiment, the display device may be realized by randomly arranging the light emitting devices on the pixel. Since the light emitting devices on the pixel has a large ratio of its largest width to its height, about 50% of the light emitting devices may be used as active light emitting devices. Since the light emitting devices are arranged on the pixel in the randomized manner, not in a regular manner, it may be possible to quicky and economically manufacture a large-area display panel.

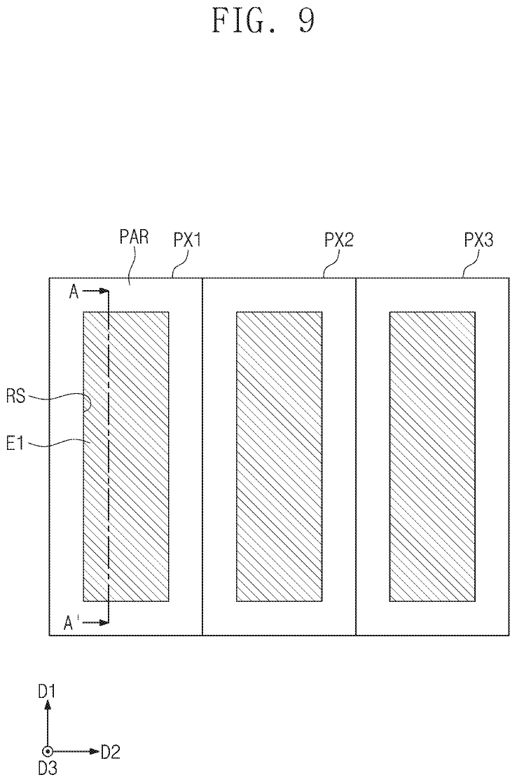

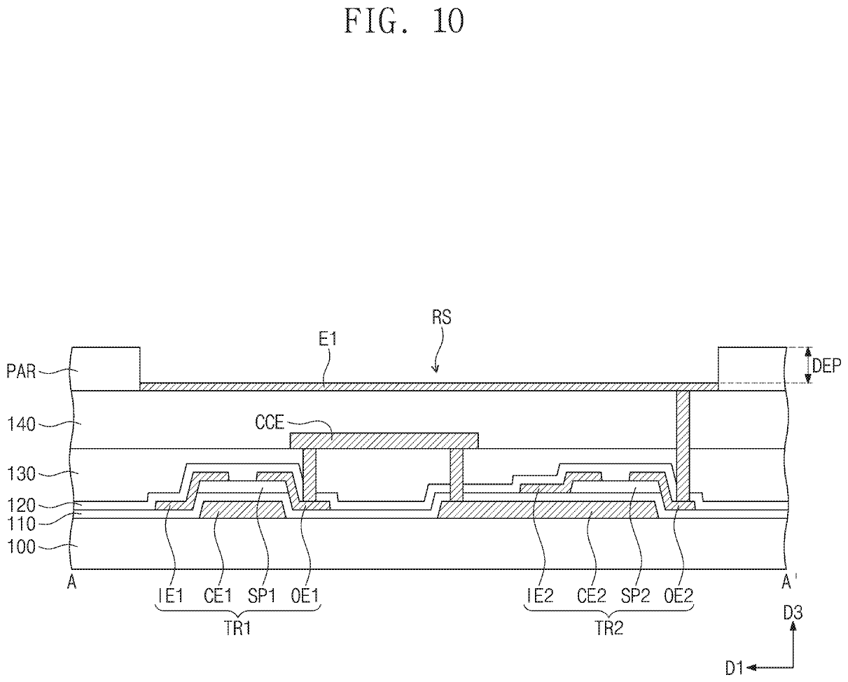

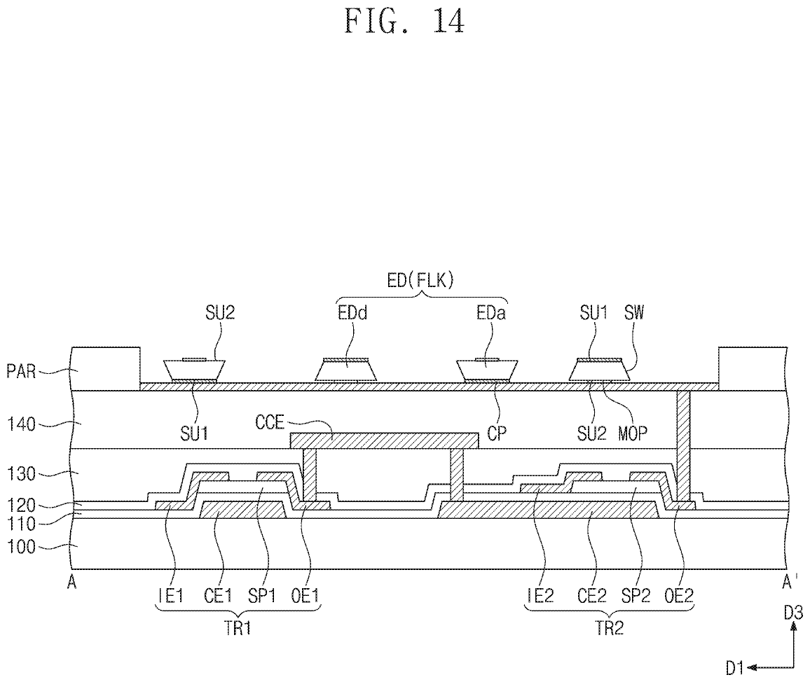

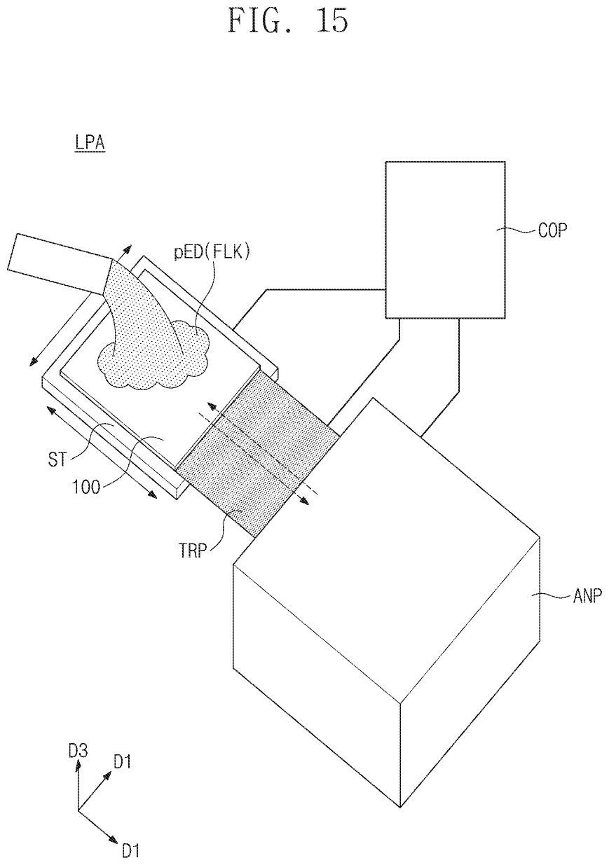

FIGS. 9, 11, and 13 are plan views illustrating a method of manufacturing a display panel of a display device according to an embodiment of the inventive concept. FIGS. 10, 12, and 14 are sectional views taken along lines A-A′ of FIGS. 9, 11, and 13, respectively. FIG. 15 is a schematic diagram illustrating an apparatus for placing light emitting devices according to an embodiment of the inventive concept.

Referring to FIGS. 9 and 10, the first thin-film transistor TR1 and the second thin-film transistor TR2 may be formed on the base layer 100. The formation of the first and second thin-film transistors TR1 and TR2 may include performing a LTPS process or a LTPO process. The connection electrode CCE may be formed to electrically connect the first and second thin-film transistors TR1 and TR2 to each other. The fourth insulating layer 140 may be formed on the connection electrode CCE. The first electrode E1 may be formed on the fourth insulating layer 140. The first electrode E1 may be electrically connected to the second thin-film transistor TR2.

The partition wall structure PAR may be formed on the fourth insulating layer 140. The partition wall structure PAR may define the recess region RS exposing the top surface of the first electrode E1. The recess region RS may be formed to have a predetermined depth DEP. The first electrode E1 on each of the first to third pixels PX1 to PX3 may be exposed through the recess region RS defined in the partition wall structure PAR.

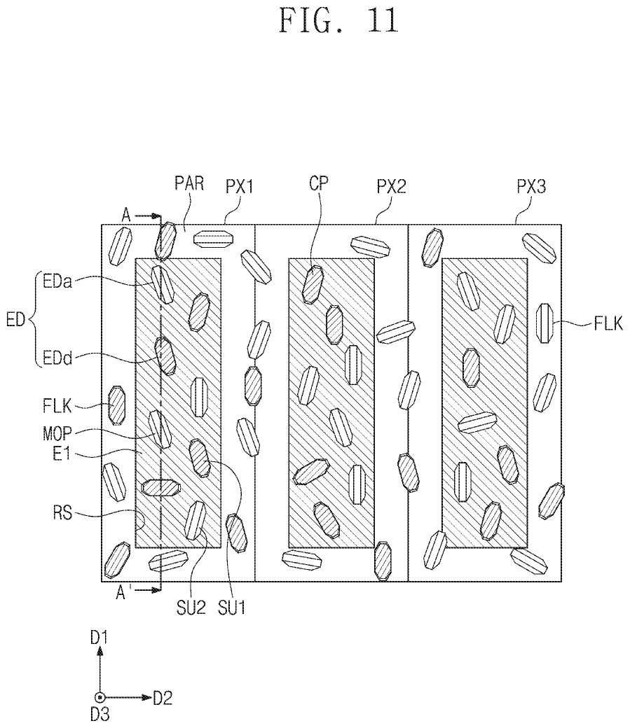

Referring to FIGS. 11, 12, and 15, a light emitting device placing apparatus LPA according to an embodiment of the inventive concept may include a stage ST, a transferring part TRP, an annealing part ANP, and a control unit COP. The stage ST may be configured to load the base layer 100 thereon. The stage ST and the annealing part ANP may be connected through the transferring part TRP. The transferring part TRP may be configured to move the base layer 100 from the stage ST to the annealing part ANP or to move the base layer 100 from the annealing part ANP to the stage ST. The control unit COP may control the stage ST, the annealing part ANP, and the transferring part TRP.

The base layer 100 (i.e., the resulting structure of FIGS. 9 and 10) may be loaded on the stage ST. Flakes FLK may be provided on the base layer 100. The flakes FLK may be the light emitting devices ED described above and may be micro-LED flakes. Each flake FLK may be an LED device having a size of several nanometers to several hundreds of micrometers, and thus, a lot of the flakes FLK may be provided in the form of powder.

The flakes FLK may be provided on the base layer 100 by supplying a light emitting device powder pED including a plurality of the flakes FLK (i.e., micro-LED flakes) on the base layer 100 (e.g., see FIG. 15).

The stage ST may be vibrated to uniformly scatter the supplied flakes FLK on the base layer 100. The stage ST may be vibrated in a first direction D1 and a second direction D2. The control unit COP may control a frequency and an amplitude in the vibrating motion of the stage ST.

According to an embodiment of the inventive concept, the light emitting device ED may have the first surface SU1 and the second surface SU2, which are opposite to each other, as described above. A connection pattern CP may be attached to the first surface SU1 of the light emitting device ED. In the light emitting device ED, a ratio of its largest width to its height may range from 1 to 100 and, in particular, from 2 to 50.

By controlling the stage ST, the flakes FLK may be uniformly scattered on the base layer 100. Each of the flakes FLK (i.e., the light emitting device ED) may be disposed in such a way that the first surface SU1 faces the base layer 100 or that the second surface SU2 faces the base layer 100. Since the light emitting device ED has a very large ratio of the width to the height, it may be hard to stand the light emitting device ED. That is, the sidewall SW of the light emitting device ED may not be disposed to face the base layer 100.

Some of the flakes FLK may be disposed on the first electrode E1 in the recess region RS and may be used as the light emitting devices ED. That is, by providing the flakes FLK onto the base layer 100, the light emitting devices ED may be formed on the first electrode E1.

The others of the flakes FLK may be disposed on the partition wall structure PAR. Some of the light emitting devices ED, which are disposed on the first electrode E1, may be disposed in such a way that the first surface SU1 thereof faces the base layer 100, and such light emitting devices ED will be mentioned as active light emitting devices EDa. The others of the light emitting devices ED, which are disposed on the first electrode E1, may be disposed in such a way that the second surface SU2 thereof faces the base layer 100, and such light emitting devices ED will be mentioned as dummy light emitting devices EDd.

Since the light emitting devices ED are randomly scattered, the light emitting devices ED may be two-dimensionally and randomly arranged on the first electrode E1. As an example, each of the light emitting devices ED on the first electrode E1 may be the active light emitting device EDa at a probability of 50% or may be the dummy light emitting device EDd at a probability of 50%.

The base layer 100 may be moved into the annealing part ANP by the transferring part TRP. The annealing part ANP may be configured to perform a thermal treatment process on the base layer 100. The connection pattern CP between the active light emitting device EDa and the first electrode E1 may be melted by the thermal treatment process and then may be adhered to the top surface of the first electrode E1. In other words, the active light emitting devices EDa may be fixedly adhered to the first electrode E1. The thermal treatment process may include a spike anneal process or an electromagnetic induction anneal process.

By contrast, the dummy light emitting devices EDd and the flakes FLK on the partition wall structure PAR may not be in contact with the first electrode E1 by the thermal treatment process, because the connection patterns CP thereof are not in contact with the first electrode E1.

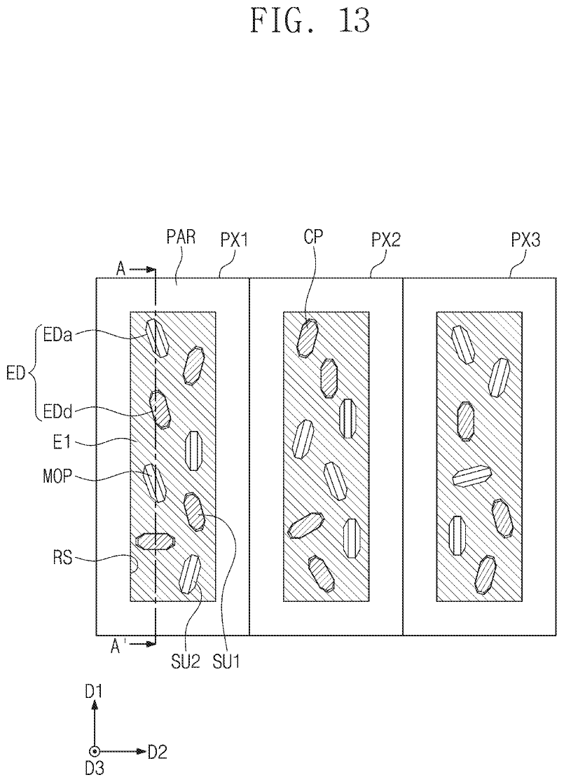

Referring to FIGS. 13, 14, and 15, the flakes FLK on the partition wall structure PAR may be removed. The removal of the flakes FLK may be performed by a method of retrieving the micro-LED flakes, which will be described below, but the inventive concept is not limited to this method.

Referring back to FIGS. 6 and 7, the fifth insulating layer 150 may be formed to fill regions between the light emitting devices ED. The second electrode E2 may be formed on the fifth insulating layer 150. The second electrode E2 may be electrically connected to the second surfaces SU2 of the active light emitting devices EDa.

The sixth insulating layer 160 may be formed on the second electrode E2. A light-blocking pattern BM and a color filter CF may be formed on the sixth insulating layer 160. The light-blocking pattern BM may be a black matrix. The color filter CF may include at least one of a red color filter, a green color filter, or a blue color filter. A cover layer CV may be formed on the light-blocking pattern BM and the color filter CF.

In the manufacturing method according to an embodiment of the inventive concept, the display device may be realized by randomly arranging the light emitting devices on the pixel. Since the light emitting devices on the pixel has a large ratio of its largest width to its height, about 50% of the light emitting devices may be used as active light emitting devices. Since the light emitting devices are arranged on the pixel in the randomized manner, not in a regular manner, it may be possible to quicky and economically manufacture a large-area display panel.

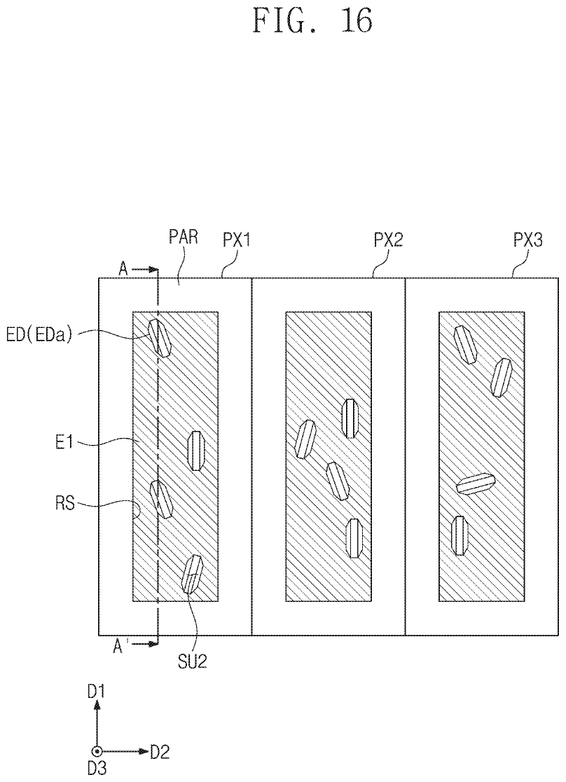

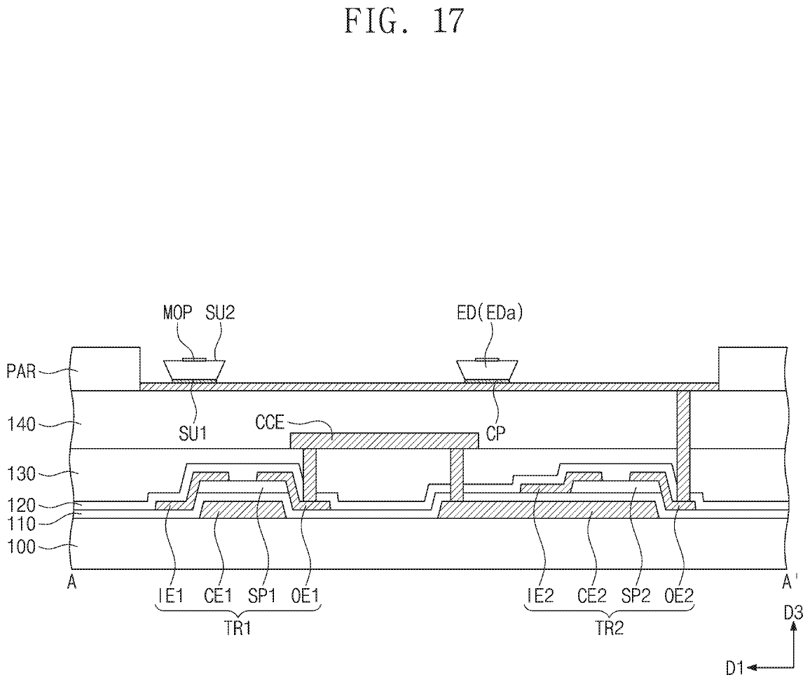

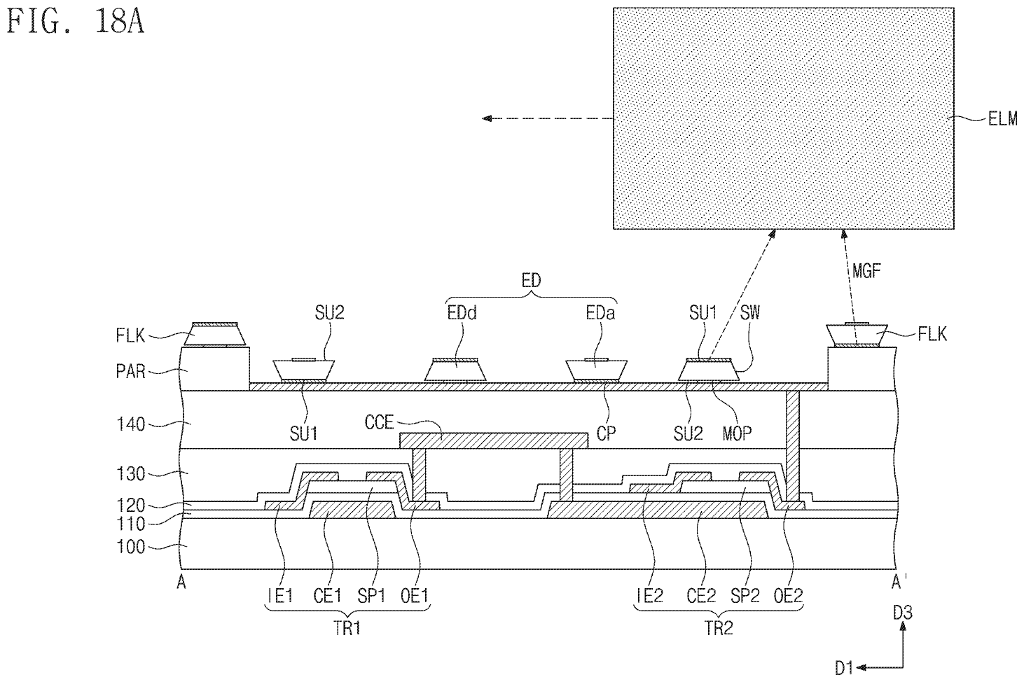

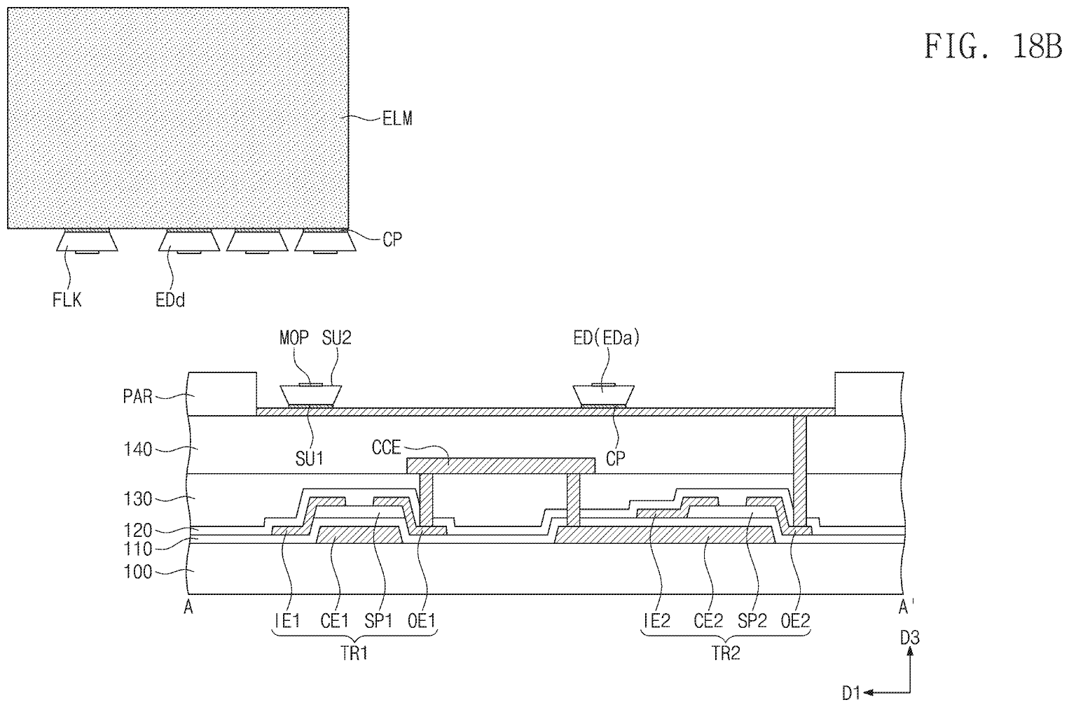

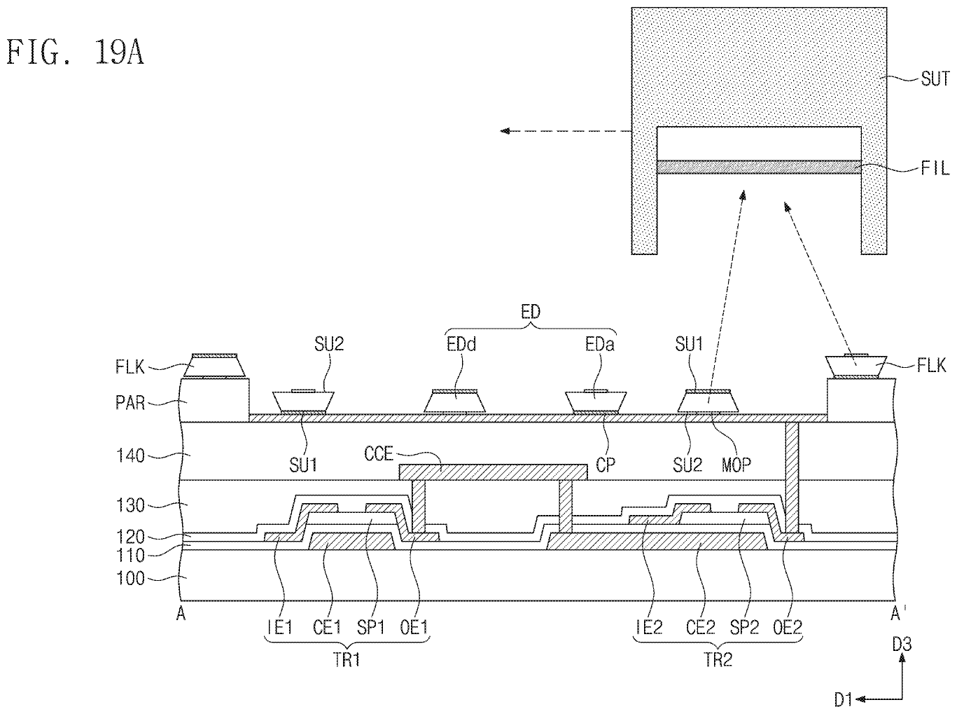

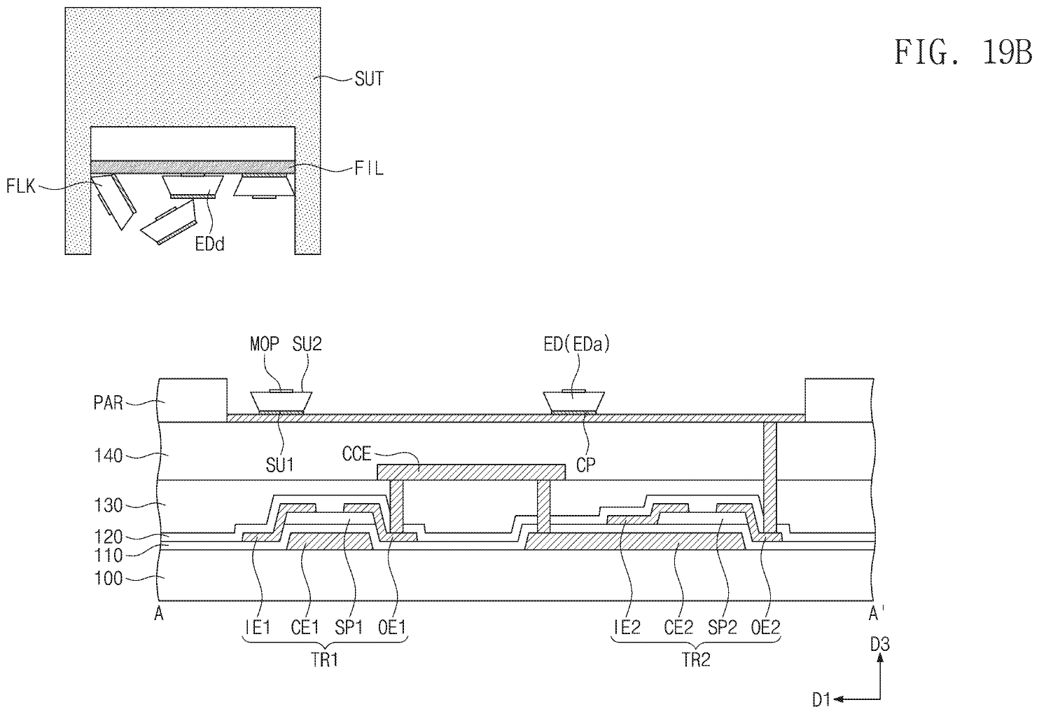

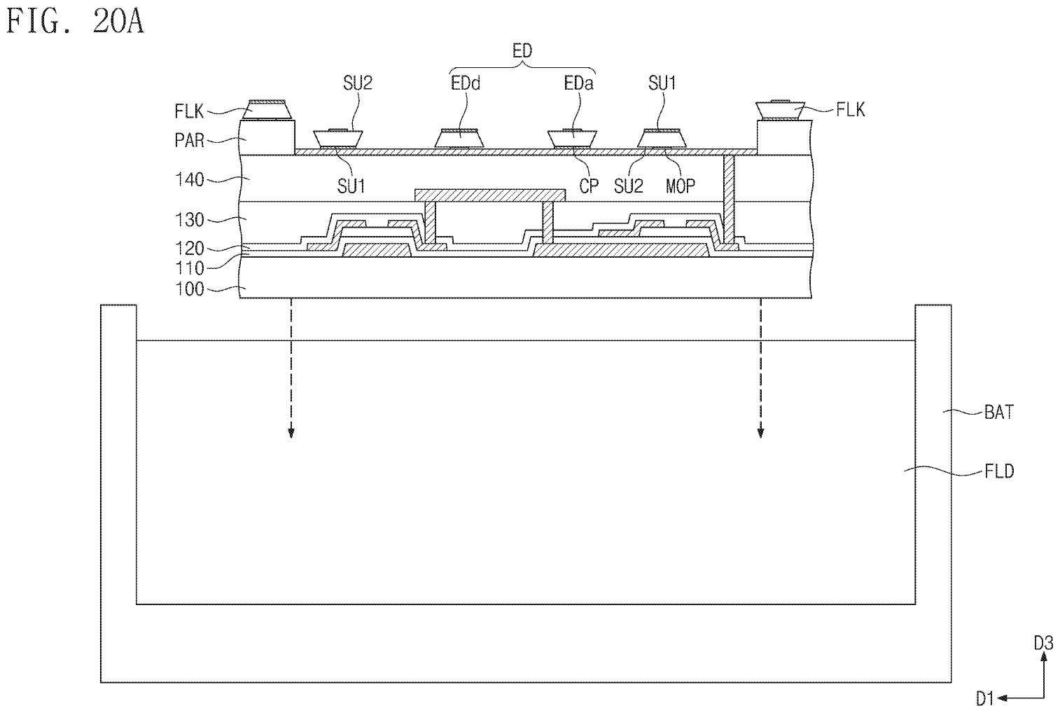

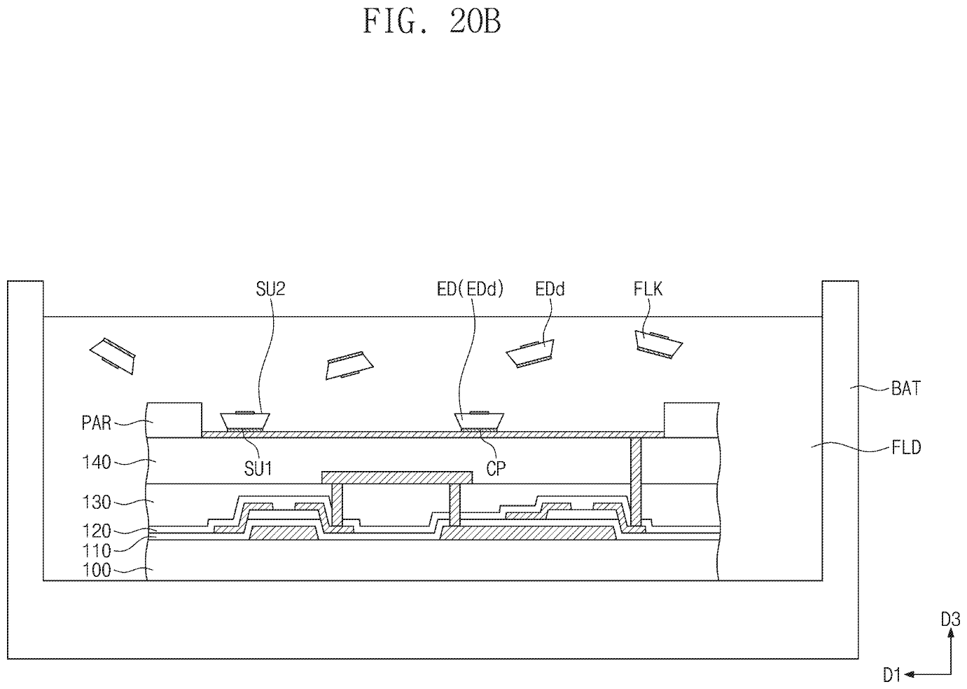

FIGS. 16, 21, and 23 are plan views illustrating a method of manufacturing a display panel of a display device, according to an embodiment of the inventive concept. FIGS. 17, 22, and 24 are sectional views taken along lines A-A′ of FIGS. 16, 21, and 23, respectively. FIGS. 18A and 18B are conceptual diagrams illustrating a method of retrieving micro-LED flakes, according to an embodiment of the inventive concept. FIGS. 19A and 19B are conceptual diagrams illustrating a method of retrieving micro-LED flakes, according to another embodiment of the inventive concept. FIGS. 20A and 20B are conceptual diagrams illustrating a method of retrieving micro-LED flakes, according to other embodiment of the inventive concept. In the following description, an element previously described with reference to FIGS. 9 to 15 may be identified by the same reference number without repeating an overlapping description thereof.

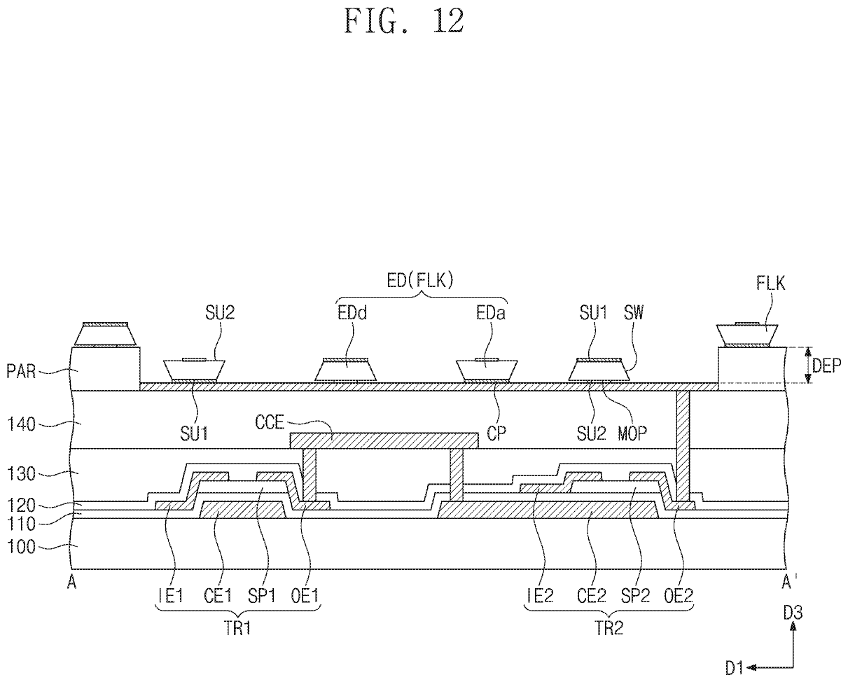

Referring to FIGS. 16 and 17, the flakes FLK, which are not adhered to an underlying pattern, may be retrieved from the resulting structure of FIGS. 11 and 12. In other words, only the active light emitting devices EDa, which are attached to the first electrode E1 by the thermal treatment process, may be left on the first electrode E1. The retrieved flakes FLK may include the dummy light emitting devices EDd on the first electrode E1 and the flakes FLK on the partition wall structure PAR.

In an embodiment, as shown in FIGS. 18A and 18B, the flakes FLK may be retrieved using an electromagnet ELM. In detail, the connection pattern CP of the flake FLK may include a magnetic metal layer (e.g., Ni). Thus, in the case where the electromagnet ELM approaches the flake FLK, an attractive magnetic force MGF may be produced between the electromagnet ELM and the connection pattern CP of the flake FLK.

For example, the electromagnet ELM may move in the first direction D1, on the base layer 100. The electromagnet ELM may approach the flakes FLK until the magnetic force MGF has a magnitude that is strong enough to levitate the flakes FLK. As the electromagnet ELM approaches the flakes FLK, the flakes FLK, which are located below the electromagnet ELM, may be attached to the electromagnet ELM. Meanwhile, the active light emitting devices EDa, which are adhered to the first electrode E1, may not be attached to the electromagnet ELM and may still be left on the first electrode E1. Accordingly, the remaining flakes FLK, except the active light emitting devices EDa, may be retrieved by the electromagnet ELM.

In another embodiment, referring to FIGS. 19A and 19B, the flakes FLK may be retrieved using a suctional tool SUT. The suctional tool SUT may be configured to produce a negative pressure and thus may inhale the air around the same. The suctional tool SUT may include a filter FIL. In an embodiment, the filter FIL may be a micro filter, through which the air, but not the flakes FLK, can pass. As the suctional tool SUT approaches the flake FLK, the flake FLK, along with the air, may be inhaled into the suctional tool SUT. In this case, owing to the filter FIL, the flake FLK may be left in an internal space of the suctional tool SUT.

For example, the suctional tool SUT may move in the first direction D1, at a level adjacent to the flakes FLK, which are arranged on the base layer 100. As the suctional tool SUT moves, the flakes FLK below the suctional tool SUT may be inhaled into the suctional tool SUT. Meanwhile, the active light emitting devices EDa, which are adhered to the first electrode E1, may not be inhaled into the suctional tool SUT and may still be left on the first electrode E1. Accordingly, the remaining flakes FLK, except the active light emitting devices EDa, may be retrieved using the suctional tool SUT and the filter FIL.

In other embodiment, referring to FIGS. 20A and 20B, the flakes FLK may be retrieved by an immersion method using fluid (i.e., solvent). In detail, a bath BAT, in which fluid FLD is contained, may be provided. For example, the fluid FLD may include deionized (DI) water or solvent (e.g., acetone). The base layer 100 provided with the flakes FLK may be placed in the bath BAT and then may be fully immersed in the fluid FLD.

In the case where the base layer 100 is immersed in the fluid FLD, the flakes FLK, which are not adhered to the first electrode E1, may be dispersed or scattered in the fluid FLD. Only the active light emitting devices EDa, which are adhered to the first electrode E1, may be left on the base layer 100. Next, the base layer 100, on which the active light emitting devices EDa are left, may be taken out from the bath BAT and then the flakes FLK dispersed in the fluid FLD may be retrieved.

FIGS. 16 and 17 illustrate an example, in which the remaining flakes FLK, except the active light emitting devices EDa, are perfectly retrieved or removed by one of the afore-described retrieving methods. However, the inventive concept is not limited to this example, and in an embodiment, at least one of the flakes FLK may not be retrieved by the retrieving method and may be left, as the dummy light emitting device EDd (e.g., see FIGS. 6 and 7), on the first electrode E1.

Referring to FIGS. 21, 22, and 15, the light emitting device powder pED may be provided again on the base layer 100, from which the flakes FLK are retrieved. Here, the light emitting device powder pED may include the flakes FLK retrieved by the afore-described method. In other words, the retrieved flakes FLK may be reused as the light emitting device powder pED. The supplying of the light emitting device powder pED may be performed using the light emitting device placing apparatus LPA previously described with reference to FIG. 15.

Some of the supplied flakes FLK may be disposed on the first electrode E1 in the recess region RS and may be used as the light emitting devices ED. Such flakes FLK may be disposed on a remaining region of the first electrode E1, except the region, to which the active light emitting devices EDa were previously attached. The flakes FLK supplied on the first electrode E1 may include the active light emitting device EDa, which is disposed to have the first surface SU1 facing the base layer 100, and the dummy light emitting device EDd, which is disposed to have the second surface SU2 facing the base layer 100. The remaining ones of the supplied flakes FLK may be disposed on the partition wall structure PAR.

Since the flakes FLK are additionally supplied on the first electrode E1 provided with the existing active light emitting devices EDa, the number of the active light emitting devices EDa on the first electrode E1 may be greater than that in the structure shown in FIG. 11.

Thereafter, a thermal treatment process may be performed on the base layer 100 using the annealing part ANP of the light emitting device placing apparatus LPA. As a result, the newly-supplied active light emitting devices EDa may be adhered to the top surface of the first electrode E1.

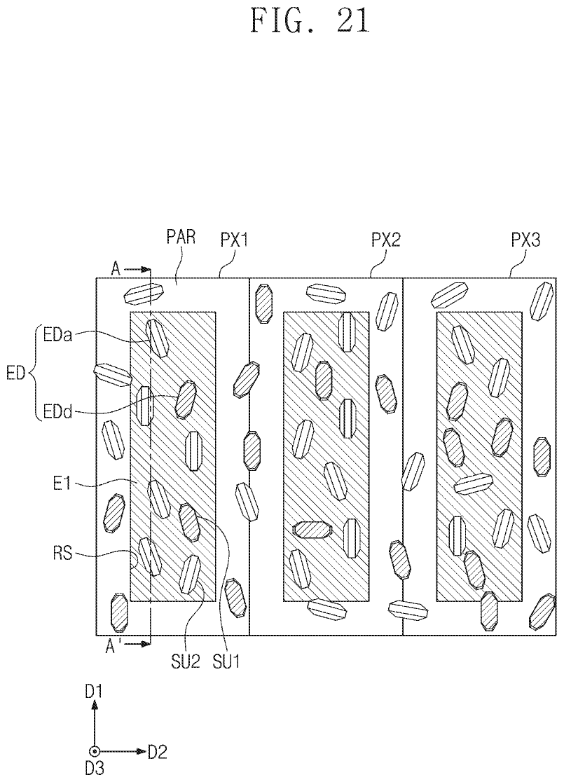

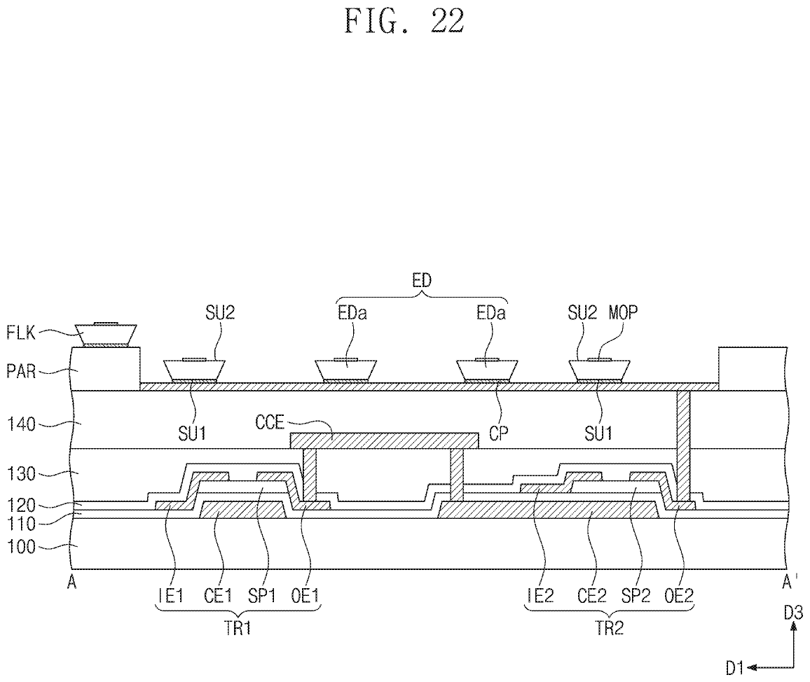

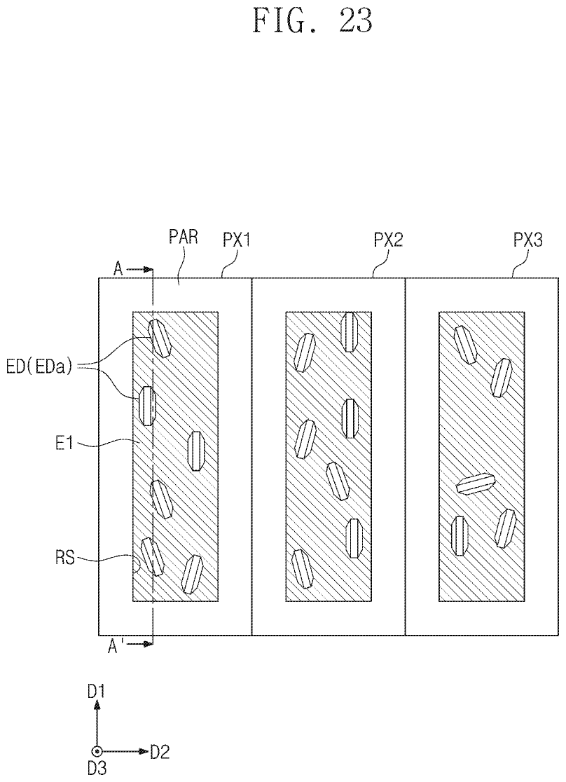

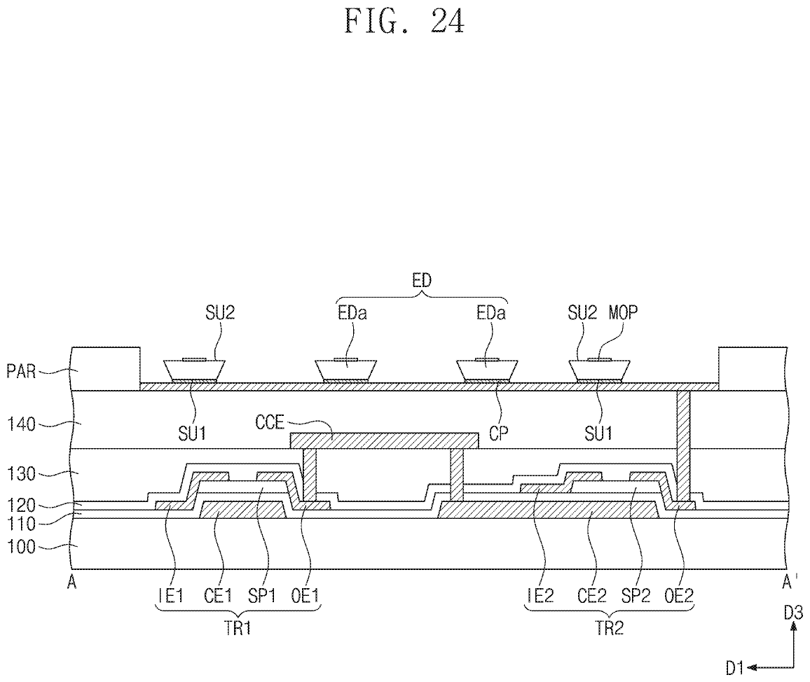

Referring to FIGS. 23 and 24, the flakes FLK, which are not attached to an underlying pattern, may be retrieved from the resulting structure of FIGS. 21 and 22. The retrieving of the flakes FLK may be performed using at least one of the retrieving methods described with reference to FIGS. 18 to 20. Since the flakes FLK, which are not adhered to the underlying pattern, are retrieved, only the active light emitting devices EDa may be left on the first electrode E1. Thereafter, as shown in FIG. 7, the second electrode E2 and the color filter CF may be formed on the light emitting devices ED.

Referring back to FIG. 23, in the display device according to the present embodiment, a density of the light emitting device may vary depending on the position of the pixel. In other words, the numbers of the light emitting devices ED, which are provided on the first to third pixels PX1 to PX3, may be different from each other. For example, the number of the light emitting devices ED in the first pixel PX1 may be six, the number of the light emitting devices ED in the second pixel PX2 may be seven, and the number of the light emitting devices ED in the third pixel PX3 may be five.

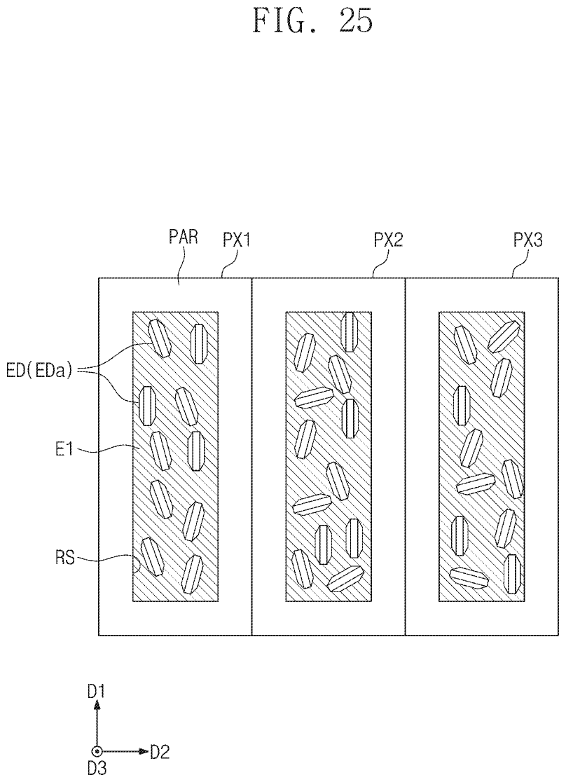

FIG. 25 is a plan view illustrating a display panel of a display device according to an embodiment of the inventive concept. Referring to FIG. 25, the density of the light emitting devices (i.e., the number of the light emitting devices ED) in each pixel may be higher than that in the embodiment previously described with reference to FIG. 23. This structure may be realized by repeating the steps previously described with reference to FIGS. 16 to 24 (e.g., the steps of supplying the flakes and retrieving the unadhered flakes).

The greater the iteration number of the flake suppling and retrieving steps, the greater the number of the active light emitting devices EDa in each of the pixels PX1 to PX3. As a result, the density of the light emitting device in each of the pixels PX1 to PX3 may be maximized, as illustrated in FIG. 25.

In detail, when viewed in a plan view, in the first pixel PX1, a ratio of a total area of the light emitting devices ED to a total area of the first electrode E1 may range from 0.5 to 0.9. That is, in the first pixel PX1, the total area of the light emitting devices ED may be larger than an area of a region of the first electrode E1, in which the light emitting devices ED are not disposed.

In a method of manufacturing a display device according to an embodiment of the inventive concept, the light emitting devices (e.g., micro-LED flakes) may be formed on a plurality, or all, of pixels, in a mass transfer manner, not by placing a light emitting device on each pixel in a pick-and-place manner Thus, it may be possible to reduce process time to manufacture a display device and to manufacture the display device in a mass production manner

According to an embodiment of the inventive concept, the micro-LED flakes, which are provided in the form of powder, may be supplied onto pixels and some of the flakes, which are not adhered to an underlying pattern, may be retrieved. The retrieved flakes may be recycled by resupplying them on the pixels. Accordingly, it may be possible to process-efficiently and cost-effectively manufacture the display device.

According to an embodiment of the inventive concept, an electromagnet, a suctional tool, or a fluid may be used to efficiently retrieve the flakes that are not adhered to the underlying pattern. Especially, it may be possible to retrieve all of the flakes, which are left on the partition wall structure between the pixels, and thereby to prevent a process failure from occurring in a subsequent process.

In a method of manufacturing a display device according to an embodiment of the inventive concept, a step of supplying micro-LED flakes on all pixels may be performed to form light emitting devices on a large-area region in a mass transfer manner Accordingly, it may be possible to reduce process time to manufacture the display device and to manufacture the display device in a mass production manner

In a method of manufacturing a display device according to an embodiment of the inventive concept, some of the micro-LED flakes, which are not adhered to an underlying pattern, may be efficiently retrieved and then may be recycled. Accordingly, it may be possible to improve process efficiency and economic efficiency in the manufacturing process. Furthermore, since the micro-LED flakes, which are not adhered to an underlying pattern, are retrieved, it may be possible to prevent a process failure from occurring in a subsequent process.

While example embodiments of the inventive concept have been particularly shown and described, it will be understood by one of ordinary skill in the art that variations in form and detail may be made therein without departing from the spirit and scope of the attached claims.

What is claimed is:

1. A display device, comprising:
a plurality of pixels on a base layer; and
a plurality of light emitting devices provided on a first pixel, which is one of the pixels,
wherein the light emitting devices comprise at least one active light emitting device and at least one dummy light emitting device,
each of the active and dummy light emitting devices comprises a first surface and a second surface, which are opposite to each other, and a metal oxide pattern on the second surface,
the first surface of the active light emitting device faces the base layer, and
the second surface of the dummy light emitting device faces the base layer.

2. The display device of claim 1, wherein an area of the first surface is smaller than an area of the second surface.

3. The display device of claim 1, wherein each of the active and dummy light emitting devices comprises a first semiconductor layer, an active layer, and a second semiconductor layer, which are sequentially stacked,
the first semiconductor layer is adjacent to the first surface, and
the second semiconductor layer is adjacent to the second surface.

4. The display device of claim 1, further comprising:
a first electrode between the light emitting devices and the base layer; and
a second electrode on the light emitting devices,
wherein the first and second surfaces of the active light emitting device face the first and second electrodes, respectively, and
the first and second surfaces of the dummy light emitting device face the second and first electrodes, respectively.

5. The display device of claim 4, wherein, when viewed in a plan view, a ratio of a total area of the light emitting devices to an area of the first electrode ranges from 0.5 to 0.9.

6. The display device of claim 1, wherein each of the active and dummy light emitting devices further comprises a connection pattern provided on the first surface.

7. The display device of claim 1, wherein the number of the active light emitting device is greater than the number of the dummy light emitting device.

8. The display device of claim 1, wherein the metal oxide pattern is provided to cover a portion of the second surface and to expose a remaining portion of the second surface.

9. The display device of claim 1, further comprising a plurality of light emitting devices provided on a second pixel, which is another of the pixels,
wherein a density of the light emitting device in the first pixel is different from that in the second pixel.

10. A method of manufacturing a display device, comprising:
forming a first electrode and a partition wall structure, which exposes the first electrode, on a base layer;
supplying micro-LED flakes on the base layer;
performing a thermal treatment process to adhere an active light emitting device, which is one of the supplied micro-LED flakes, to the first electrode; and
retrieving the remaining ones of the micro-LED flakes, except the active light emitting device adhered to the first electrode.

11. The method of claim 10, wherein the retrieving of the micro-LED flakes comprises providing an electromagnet on the base layer to attach the remaining ones of the micro-LED flakes to the electromagnet.

12. The method of claim 11, wherein each of the micro-LED flakes comprises a magnetic metal layer provided on one of surfaces thereof.

13. The method of claim 10, wherein the retrieving of the micro-LED flakes comprises providing a suctional tool on the base layer to inhale the remaining ones of the micro-LED flakes into the suctional tool.

14. The method of claim 13, wherein the suctional tool comprises a micro filter, which prevents the micro-LED flakes from passing therethrough.

15. The method of claim 10, wherein the retrieving of the micro-LED flakes comprises immersing the base layer in fluid to disperse the remaining ones of the micro-LED flakes in the fluid.

16. The method of claim 10, wherein the supplying of the micro-LED flakes on the base layer and the retrieving of the remaining ones of the micro-LED flakes are repeatedly performed.

17. The method of claim 10, further comprising resupplying the retrieved micro-LED flakes on the base layer.
